(19) United States
(12) Patent Application Publication
(10) Pub. No.: US 2026/0044645 A1
(43) Pub. Date: Feb. 12, 2026

(54) GENERATION OF FUSED ENVIRONMENTAL AND COMPOSITIONAL INFORMATION

(71) Applicant: Gamma Reality, Inc., Richmond, CA (US)

(72) Inventors: Andrew Robert Haefner, Berkeley, CA (US); Ryan Thomas Pavlovsky, Pleasant Hill, CA (US)

(21) Appl. No.: 18/797,206

(22) Filed: Aug. 7, 2024

(51) Int. Cl. G06F 30/25

(52) U.S. Cl. CPC G06F 30/25

(57) ABSTRACT

A compositional visualization system comprises a sensor to collect contextual information, a particle generator to generate a first stream of one or more types of particles, and a detector to receive a second stream of one or more detectable products. The second stream is generated by interaction of the first stream with the environment. The system further comprises computer-executable instructions to cause the system to transform the received second stream into compositional data, and merge the compositional data with the contextual information to generate a merged digital representation. The merged digital representation can be displayed at one or more devices and can also be used directly to drive autonomous robotic systems.

### BACKGROUND

Detection of compositional information (such as elemental, chemical, isotopic, or physical) of an environment may provide useful information for a variety of applications, including nuclear security and safety, emergency response, consequence management, explosives detection, and contamination remediation. This compositional information can be attained by actively generating particles to probe an environment. However, use of solely compositional characteristics without contextual information to describe the environment may lack sufficient detail to identify what objects or features in the environment specific compositional characteristics may correspond to. Furthermore, obtaining additional information regarding the compositional characteristics as well as corresponding environmental objects or features may facilitate more efficient deployment of a device used to detect the compositional characteristics.

### BRIEF DESCRIPTION OF THE DRAWINGS

Various techniques will be described with reference to the drawings, in which:

FIG. 1 illustrates a compositional visualization system, in accordance with an embodiment;

FIG. 2 illustrates a first embodiment of an assembly for the compositional visualization system of FIG. 1, in accordance with an embodiment;

FIG. 3 illustrates a second embodiment of an assembly for the compositional visualization system of FIG. 1, in accordance with an embodiment;

FIG. 4 illustrates movement of a data collection and fusing assembly of a compositional visualization system, in accordance with an embodiment;

FIG. 5 illustrates an example of a visual display of data collected by a compositional visualization system, in accordance with an embodiment;

FIG. 6 illustrates a first example of a workflow for a compositional visualization system, in accordance with an embodiment;

FIG. 7 illustrates a second example of a workflow for a compositional visualization system, in accordance with an embodiment;

FIG. 8 illustrates a third example of a workflow for a compositional visualization system, in accordance with an embodiment;

FIG. 9 illustrates a method for operating a compositional visualization system, in accordance with an embodiment;

FIG. 10 illustrates a method for using contextual information to guide operation of a compositional visualization system, in accordance with an embodiment; and

FIG. 11 illustrates an environment in which various embodiments can be implemented.

### DETAILED DESCRIPTION

The present application describes systems and techniques to fuse contextual information collected by a compositional visualization system with compositional measurements obtained by the system. In at least one embodiment, the compositional visualization system includes a sensor to collect contextual information of an environment, a particle generator to generate, based, at least in part, on the contextual information, a first stream comprising one or more types of particles, and a detector to receive a second stream comprising one or more detectable products. The second stream of particles is generated by interaction of the first stream with the environment. The compositional visualization system further includes one or more processor and memory that includes computer-executable instructions. When executed, the computer-executable instructions cause the system to transform reception of the second stream into compositional data, and merge the compositional data with the contextual information of the first sensor to generate a merged digital representation.

In at least one embodiment, a method for compositional visualization includes obtaining contextual information of an environment from a sensor, generating, at a particle generator, based, at least in part, on the contextual information, a first stream comprising one or more types of particles, and receiving a second stream comprising one or more detectable products at a detector. The second stream is generated by interaction of the first stream with the environment. The method further includes transforming the second stream into compositional data, and merging the compositional data with the contextual information of the first sensor to generate a merged digital representation.

In at least one embodiment, a deployable apparatus for compositional visualization includes one or more processors and memory, including computer-executable instructions. When executed by the one or more processor, the computer-executable instructions cause the apparatus to generate a model of an environment using contextual information collected by a sensor, and generate measurements of one or more attributes of the environment using data obtained by a detector. In the embodiment, the detector is to detect a set of detectable products produced via interactions of a set of particles with the environment at a location identified based, at least in part, on the contextual information. The computer-executable instructions further cause the apparatus to combine the measurements of the one or more attributes with the model of the environment to generate a fused representation, and update the fused representation based, at least in part, on changes to the contextual information collected by the sensor.

Techniques described and suggested in the present disclosure improve the field of remote probing of an environment. Additionally, techniques described and suggested in the present disclosure improve the efficiency/functioning of apparatuses for analysis of environmental attributes by incorporating a mechanism that allows targeted identification of objects in an environment and measurement of attributes of the objects in a remote and non-destructive manner. For example, the systems and apparatuses describe herein may locate an object that may otherwise be hidden from view and provide compositional information regarding the object, where the compositional information includes information regarding at least chemical, isotopic, and physical composition. Furthermore, compositional analysis of objects in motion, in addition to that of stationary objects is achieved. Moreover, techniques described and suggested in the present disclosure are necessarily rooted in computer technology in order to overcome problems specifically arising with fusing contextual information of an environment, such as a two-dimensional (2D) or three-dimensional (3D) model of the environment, with analytical information of the environment, such as compositional measurements. Further, the techniques of this disclosure overcome these problems by a customizable system that updates a display of information to a user in real-time, thereby compiling different data types into a single cohesive digital representation that can be readily controlled and adjusted by the user.

In the preceding and following description, various techniques are described. For purposes of explanation, specific configurations and details are set forth in order to provide a thorough understanding of possible ways of implementing the techniques. However, it will also be apparent that the techniques described below may be practiced in different configurations without the specific details. Furthermore, well-known features may be omitted or simplified to avoid obscuring the techniques being described.

Any system or apparatus feature as described herein may also be provided as a method feature, and vice versa. System and/or apparatus aspects described functionally (including means plus function features) may be expressed alternatively in terms of their corresponding structure, such as a suitably programmed processor and associated memory. It should also be appreciated that particular combinations of the various features described and defined in any aspects of the present disclosure can be implemented and/or supplied and/or used independently.

The present disclosure also provides computer programs and computer program products comprising software code adapted, when executed on a data processing apparatus, to perform any of the methods and/or for embodying any of the apparatus and system features described herein, including any or all of the component steps of any method. The present disclosure also provides a computer or computing system (including networked or distributed systems) having an operating system that supports a computer program for carrying out any of the methods described herein and/or for embodying any of the apparatus or system features described herein. The present disclosure also provides a computer readable media having stored thereon any one or more of the computer programs aforesaid. The present disclosure also provides a signal carrying any one or more of the computer programs aforesaid. The present disclosure extends to methods and/or apparatus and/or systems as herein described with reference to the accompanying drawings. To further describe the present technology, examples are now provided with reference to the figures.

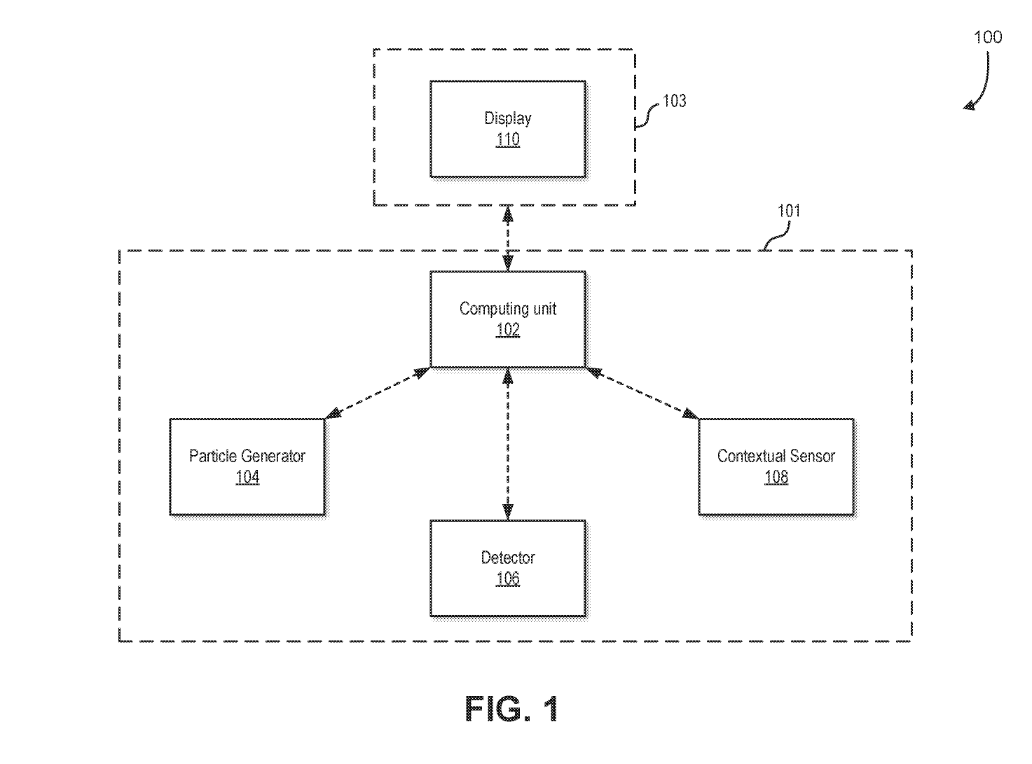

FIG. 1 illustrates a compositional visualization system 100 which may be used to generate a visual display of environmental information. In at least one embodiment, the compositional visualization system 100 may include one or more deployable apparatuses that may be controlled remotely and transmit data to remote devices. In at least one embodiment, the compositional visualization system 100 may include a first portion 101, which may be a data collection and fusing assembly 101, and a second portion 103, which may be a visualization device 103. In some instances, the visualization device 103 may be located at an apparatus that includes the data collection and fusing assembly 101, e.g., the visualization device 103 may be coupled to the data collection and fusing assembly 101. In other embodiments, however, the visualization device 103 may be positioned at a distance away from the data collection and fusing assembly 101 such that the visualization device 103 is spaced away and separate from the data collection and fusing assembly 101 to operate as a remote visualization device 103. In yet other embodiments, the compositional visualization system 100 may include more than one of the visualization device 103, which may be placed in different locations relative to the data collection and fusing assembly 101. For example, the compositional visualization system 100 may include one visualization device 103 that is coupled to the data collection and fusing assembly 101 and one or more additional visualization devices 103 that are positioned away from the data collection and fusing assembly 101.

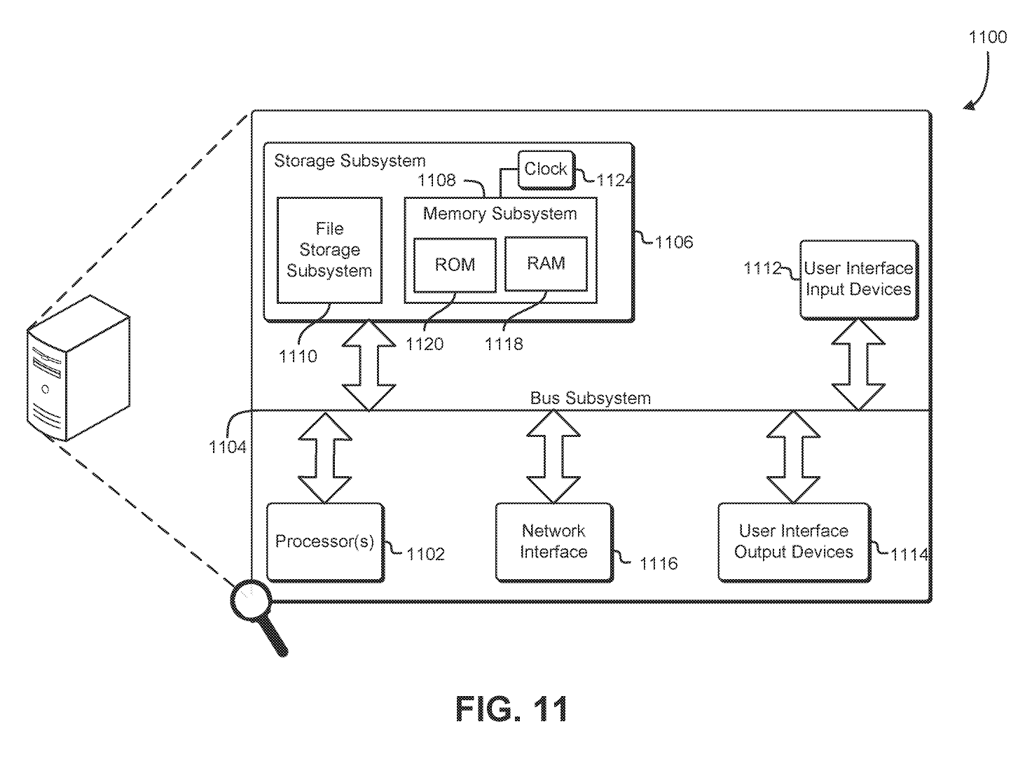

In at least one embodiment, the data collection and fusing assembly 101 may include devices to collect data regarding an environment surrounding at least a portion of the data collection and fusing assembly 101. In at least one embodiment, the data collection and fusing assembly 101 may include a computing unit 102, a particle generator 104, a detector 106, and a contextual sensor 108. The computing unit 102, as an example, may include one or more processors and memory that includes computer-executable instructions to implement various algorithms in conjunction with operation of other components of the compositional visualization system 100. The computing unit 102 may further store, or obtain from another storage device, and execute computer-executable instructions to receive, process (e.g., performing computations thereon), transform, and compile data, and generate a visualization of the data. Furthermore, the computing unit 102 may also store, or obtain from another storage device, computer-executable instructions to coordinate operation of the components of the compositional visualization system 100 to use data obtained via operation thereof to generate the visualization of the data. For example, the computing unit 102 may be an embodiment of a computing device 1100 depicted in FIG. 11 and described further below.

In at least one embodiment, the computing unit 102 may send commands to the particle generator 104, the detector 106, and the contextual sensor 108 to implement activation and deactivation thereof. The computing unit 102 may also, in at least one embodiment, receive data collected by the detector 106 and/or the contextual sensor 108 and merge the collected data to generate a single visualization of the collected data. For example, the computing unit 102 may include software (e.g., algorithms) to analyze and transform data received from the detector 106 into a format that may allow the data to be aligned and combined with data received from the contextual sensor 108, as described further below. In at least one embodiment, the computing unit 102 may implement algorithmic alarming software that identifies a presence of elements or chemicals of interest and correlates their presence with a map of the environment generated by the contextual sensor 108.

In at least one embodiment, the algorithmic alarming software may be performed according to the data collected by the detector 106. For instance, raw data collected by the detector 106 may be transformed into spectral data via processing by a processor at the detector 106 and/or by the computing unit 102, and the spectral data may be separated into time bins as well as energy and/or wavelength bins. Peaks in the spectral data may be identified and correlated with a location of the data collection and fusing assembly 101, as determined using contextual data collected by the contextual sensor 108. In at least one embodiment, by employing advanced algorithms and machine learning, gross features of the spectra may be detected and identified. This may allow changes in the spectral data to be tracked over time and correlated with positional changes from a specific signature that occurs at a particular wavelength or energy, or combination of wavelengths or energies.

In at least one embodiment, the algorithmic alarming software may further be used to perform spectral decomposition to decompose the spectra into components of interest. The components of interest may be tracked and correlated with the contextual data. For example, if simultaneous localization and mapping (SLAM) and 3D tracking are implemented at the contextual sensor 108, the components of interest may be tracked to be correlated over space.

Furthermore, in at least one embodiment, algorithms used to collect and process data at the detector 106 may be coupled with the contextual data to further enhance or augment the detection capabilities of the detector 106. The resulting information obtained by coupling the detection algorithms with the contextual data may be used statistically as prior information to inform and guide the detection and alarming algorithms. In at least one embodiment, alarming, as facilitated by the algorithmic alarming software, may be output according to thresholds corresponding to specific parameters, which may include any of the detection and decomposition processes described above. The alarming software algorithms may also be used to generate confidence intervals for computed values to indicate a likelihood that an implemented alarm is correct based on statistical information computed from the collected data. Moreover, various other detection and alarming algorithms may be similarly applied to analyze and process any combination of data streams obtained from the particle generator 104, the detector 106, and the contextual sensor 108.

In at least one embodiment, the computing unit 102 may be communicatively coupled to the particle generator 104, the detector 106 and the contextual sensor 108 to allow information to be exchanged between these devices. For example, the computing unit 102 may be coupled to each of the devices via a hardwired connection. In other examples, one or more of the particle generator 104, the detector 106 and the contextual sensor 108 may be coupled to the computing unit 102 by a wireless connection. In at least one embodiment, the computing unit 102 may be further communicatively coupled to the visualization device 103 by a hardwired connection or a wireless connection.

In at least one embodiment, the particle generator 104 may generate one or more types of particles which may be expelled from the particle generator 104 along a path to direct the particles to a target region of the environment. In at least one embodiment, the particle generator 104 may produce a stream of one or more particles. For example, the stream of particles may include one or more of neutrons, alpha particles, electrons, x-rays, lasers (e.g., photons), among others. In yet another embodiment, the particle generator may generate a set of particles that are to interact with the environment. For example, the particle generator 104 may receive a command from the computing unit 102 to activate components of the particle generator 104 to emit the particles. In at least one embodiment, the particle generator 104 may be a neutron generator 104 that generates and emits a stream of neutrons. The neutrons, upon contacting (e.g., interrogating) an object in the environment, may cause one or more gamma-rays to be emitted from the object where the gamma-rays may be emitted with signatures specific to a material that the neutrons come into contact with. In least one embodiment, the gamma-rays may be detected by the detector 106, as well as any neutrons that may also be produced during interrogation of an object by the neutron generator 104. Furthermore, in at least one embodiment, the detector 106 may also detect alpha particles produced during neutron generation at the neutron generator 104.

In at least one embodiment, the neutron generator 104 may be a deuterium-tritium associated particle imaging (D-T API) neutron generator to be used to perform analysis of one or more attributes or a region of the environment or of an object in the environment and to add imaging and location-specific information to the analytical results. For example, the D-T API neutron generator may produce neutrons by ionizing deuterium and tritium atoms and accelerating the ions into a metal hydride target which facilitates a fusion reaction of the ions. Fusion of a deuterium ion to a deuterium ion may generate a helium-3 ion, while fusion of deuterium ion to a tritium ion may generate a helium-4 ion (e.g., an alpha particle) and a neutron. The alpha particle may be detected by a position sensitive alpha detector which may be included at one or more of the neutron generator 104 or the detector 106 and the neutron may be emitted from the neutron generator 104 to enter, for example an object of interest in the environment. One or more gamma-rays may be emitted from the object which may be detected and measured by the detector 106.

In other embodiments, the particle generator 104 may be of another type of neutron generator other than a DT-API neutron generator, such as other D-T neutron generators, a deuterium-deuterium (D-D) neutron generator, or a tritium-tritium (T-T) neutron generator, among others. For example, in another embodiment, the neutron generator 104 may not include API. In yet other embodiments, one or more of the particle generator 104 may be included in the data collection and fusing assembly 101, which may include neutron generators and/or other types of particle generators. For example, the particle generators may include one or more x-ray generators and/or one or more spectroscopic devices. The spectroscopic devices may include a Raman spectrometer. In at least one embodiment, multiple neutron generators may be used which may include any one of the types of neutron generators discussed above, or any combination thereof.

For any type or combination of neutron generator used, bulk responses from detected neutrons or gamma-rays may be used to infer properties of the environment, e.g., a targeted region of the environment. The software at the computing unit 102 may include, in at least one embodiment, algorithms to convert the neutrons and gamma-rays into a measurement of one or more attributes of the environment, including, but not limited to, chemical compositions such as elemental composition and elemental ratios, isotopic compositions, as well as physical compositions, such as density, of an object or a region of the environment the neutron generator is interrogating. It will be noted that attributes and composition may be used interchangeably herein, where reference to attributes or composition refer to chemical, isotopic, and physical composition. The attribute measurements may be computed from spectral information of the neutrons and gamma-rays and/or timing information, as described below. In at least one embodiment, the timing information may be computed relative to correlated neutrons or pulsed interrogation performed via the neutron generator.

In at least one embodiment, the detector 106 may receive one or more detectable products that are produced by interaction of a stream or set of particles with the environment. In at least one embodiment, the detector 106 may receive a stream of one or more detectable products. In yet another embodiment, the detector 106 may detect a set of detectable products. For example, the detector 106 may detect one or more of neutrons, alpha particles, and gamma-rays during interrogation of the environment using the particle generator 104. The detector 106 may be positioned and/or oriented relative to the particle generator 104 depending on a specific type of particle generation and detection being performed, e.g., relative to a neutron generator, an x-ray generator, or a Raman spectroscopy light source. In at least one embodiment, components to detect a specific type of detectable product may be implemented at the detector 106 and data collected by the components may be transmitted to the computing unit 102 for processing. For example, the software at the computing unit 102 may receive the collected data from the detector 106, which may include, for example, spectral or spectrometric data, and may perform quantitative analysis on the collected data to yield quantitative results.

As an example, in instances where the neutron generator 104 is the D-T API neutron generator, interaction of the neutron with nuclei of a material of the object may stimulate the nucleus to release a gamma-ray. The gamma-ray may leave the object, e.g., be emitted from the object, to be detected at a gamma-ray detector, which may be included in the detector 106. Detection of the alpha particles and the gamma-ray may be transmitted to the computing unit 102 from the detector 106 (and from the particle generator 104 in examples where the alpha particle detector is located thereat), and time-synced electronics of the computing unit 102 may compute a time difference between detection and measurement of the alpha particle and detection and measurement of the gamma-ray. In at least one embodiment, the time difference may indicate a distance between the neutron generator 104 and the point of interaction between the neutron and the object, which may allow a 3D position of the point of interaction to be identified.

As an example, the point of interaction may include x, y, z coordinates and energy values relative to the D-T API neutron generator. In at least one embodiment, the energy values of points of interaction computed by the computing unit 102 may be transposed into histograms to generate a gamma-ray spectrum for each point of interaction such that a characteristic gamma-ray spectrum may be produced for each 3D position in the environment relative to the D-T API system. When the gamma-ray spectra (e.g., spectral data) are coupled to a global frame (e.g., world coordinates), as described further below, compositional information may be fused with spatial information to allow a merged digital representation of a composition of an environment to be generated.

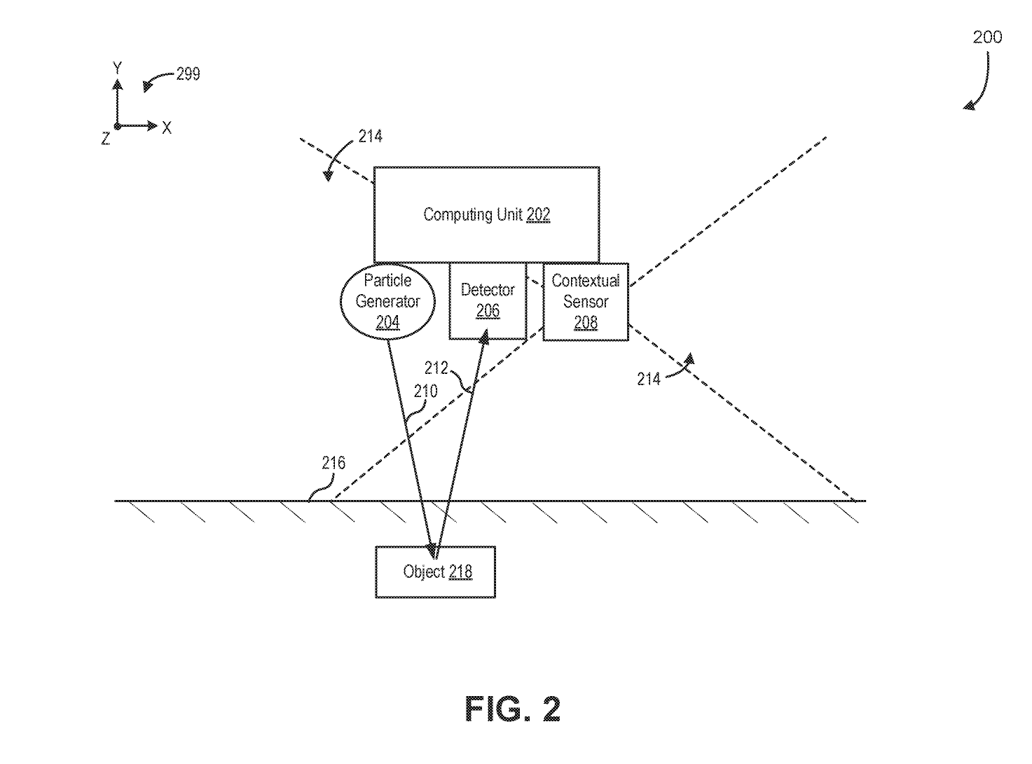

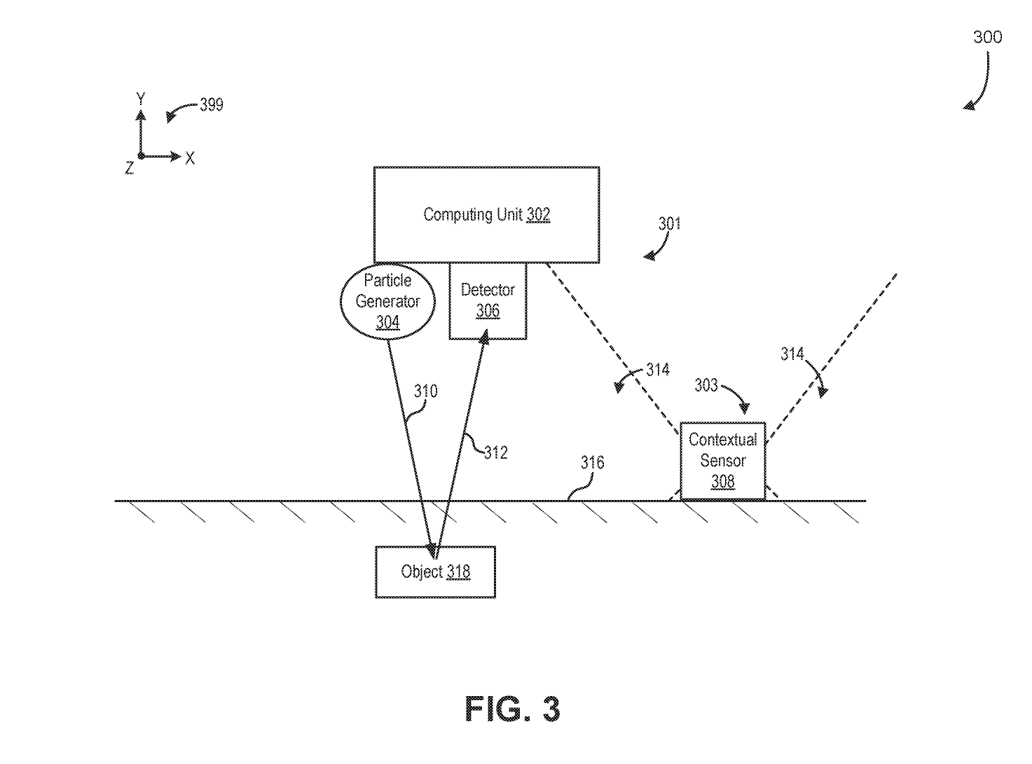

In at least one embodiment, the measured attributes of the environment may be overlaid, merged, fused, or otherwise combined with data collected from within a field of view of the contextual sensor 108. It will be appreciated that although one contextual sensor 108 is depicted in FIG. 1 (as well as in FIGS. 2 and 3), the data collection and fusing assembly 101 may include more than one contextual sensor 108. For example, the data collection and fusing assembly 101 may incorporate contextual sensors 108 of different types and compile data obtained by the contextual sensors 108 into a single visualization of the data, along with the data from the detector 106. In at least one embodiment, the contextual sensor 108 may be any type of device capable of obtaining contextual information of the environment within its field of view, such as location, geometry, and/or orientation of objects in the environment. In at least one embodiment, the contextual sensor 108 may generate 2D, 3D, or higher dimensional models of the environment. For instance, the model may be include a point cloud, a mesh, a volume, or some other type of model.

In at least one embodiment, the contextual sensor 108 may include a light detection and ranging (LiDAR) system. For example, the LiDAR system may include a light source, such as a laser source, to irradiate a target with light (e.g., a laser) and measure an amount of time for the light to be reflected and received at a receiver of the LiDAR system. In at least one embodiment, the LiDAR system may perform 3D mapping using SLAM or another method that produces similar results to those of SLAM. In yet other embodiments, the contextual sensor 108 may include one or more of a camera, a radar system, a video camera, an x-ray source, or any other type of sensor for obtaining 2D and/or 3D information of an environment. In at least some instances more than one type of contextual sensor 108 may be utilized. The contextual information collected by the contextual sensor 108 may include SLAM data, 2D or 3D images, reflected energy, x-ray images, radar, IR images, multispectral images, heat images, etc. In at least one embodiment, when combined with measurements from a D-T API neutron generator, the contextual sensor 108 may provide mapping of objects that are visible or unhidden behind or within another object or medium while the D-T API neutron generator may provide mapping of objects or media that may not be visible, or may be hidden behind or within another object or medium. In at least one embodiment, the contextual sensor 108 may be used to track a location of the particle generator 104 and the detector 106 within the environment. The tracked location may be used to orient and guide repositioning of the data collection and fusing assembly 101.

Alternatively, when the contextual information is correlated to x-ray data collected from an x-ray detector implemented at the detector 106, 3D x-ray imaging of an environment may be accomplished. Similarly, when the particle generator 104 and the detector 106 are configured as a Raman spectrometer, 3D mapping of a chemical composition of an environment may be obtained. For example, the particle generator 104 may include a light source, such as a laser, and the detector 106 may be configured to detect light. Furthermore, depending on what type of particle generator or combination of particle generator types is used at the data collection and fusing assembly 101, various types of compositional mapping of an environment may be acquired.

In at least one embodiment, the contextual sensor 108 may also be used to activate automated shutoff or deactivation of the particle generator 104 to mitigate exposure of an operator to the generated particles. For example, upon detection of a person approaching within a threshold distance of the data collection and fusing assembly 101 by the contextual sensor 108, the computing unit 102 may command deactivation of the particle generator 104. In yet another embodiment, once the contextual information from the contextual sensor 108 indicates that the person has moved beyond the threshold distance, the particle generator 104 may be automatically re-activated.

In at least one embodiment, the contextual information obtained by the contextual sensor 108 may be processed by the software at the computing unit 102 to generate a map of the environment. For example, the computing unit 102 may implement SLAM algorithms to produce a 3D map of the environment. Furthermore, in at least one embodiment, the contextual information may be algorithmically combined with the data obtained from interrogation of the environment with the particle generator 104. In at least one embodiment, the combining of the data from the detector 106 with the contextual information may include combining data streams to perform data fusion.

In some instances, the computing unit 102 may store or receive, e.g., from another computing unit or computing device, a previously generated, e.g., a pre-existing, model of the environment or at least a portion of the environment. The previously generated model may be used alternatively or in addition to the contextual information from the contextual sensor 108. For example, the contextual information may be used to track a position of the particle generator 104 and the detector 106 in the environment and data obtained by interrogation with the particle generator 104 may be combined or fused with the pre-existing model.

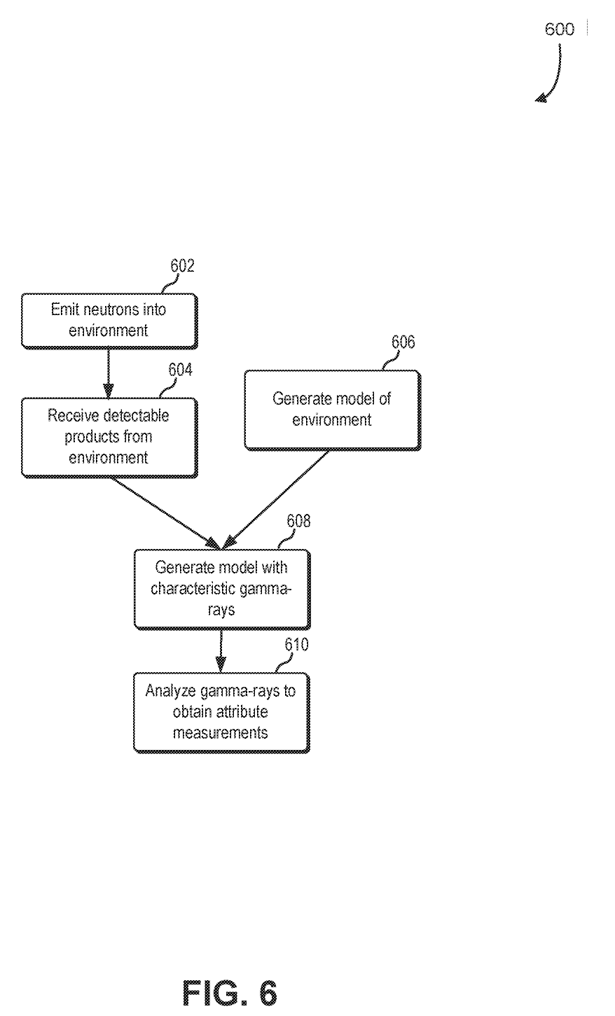

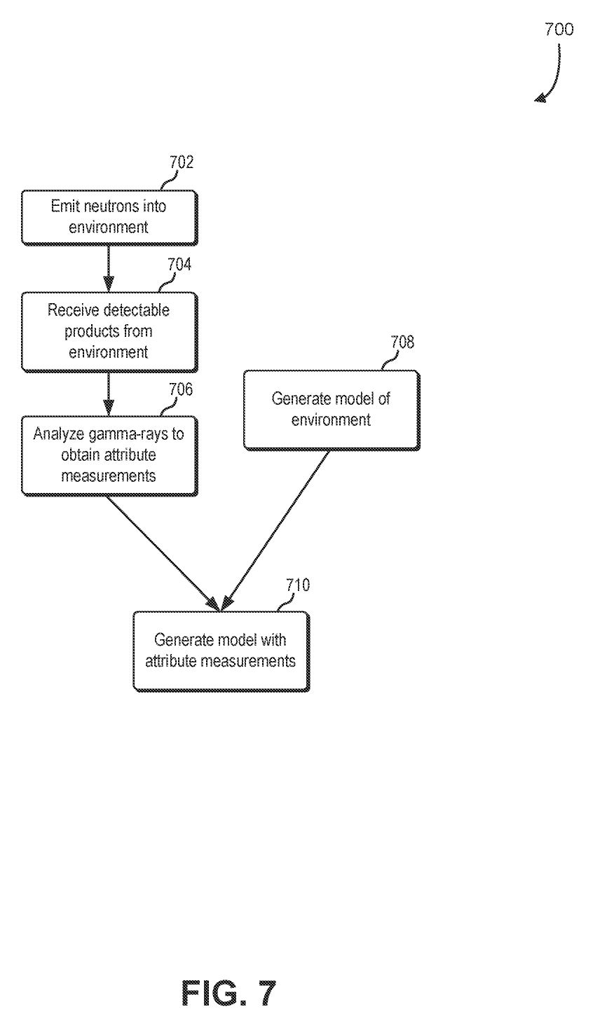

In at least one embodiment, data fusion may include combining the data from the detector 106 and the contextual information received from the contextual sensor 108 (where the data and the contextual information are collectively referred to as collected data hereafter) by correlating the collected data according to time. The data from the detector 106 may be processed and transformed into measurements of one or attributes prior to data fusion or may be processed and transformed after data fusion, as shown in FIGS. 6 and 7. For example, generation of histograms of the gamma-ray spectra may be performed after conversion to a world coordinate frame, as described further below, or may be performed before conversion to the world coordinate frame and directly on list mode events. In at least one embodiment, the contextual sensor 108 may utilize a respective coordinate frame in x, y, and z coordinates and a relative positioning of the particle generator 104 and the detector 106 may be predetermined. For example, a distance and orientation of the particle generator 104 and the detector 106 may be known based on a fixed physical arrangement of the components of the data collection and fusing assembly 101.

Furthermore, a 3D “world” coordinate system may be created for the environment, e.g., the object or region of interest. In examples, where the particle generator 104 is a D-T API neutron generator, a time correlation between the D-T API data (e.g., having coordinates of x, y, z, and an energy value) and the known position of the data collection and fusing assembly 101 may be applied, which allows the detected characteristic gamma-ray data to be geometrically transformed into a world model according to the world coordinates (e.g., to a world coordinate frame). Characteristics of each gamma-ray spectrum may be further processed at the computing unit 102 to compute measurements of one or more compositions of the object.

As an example, the fusing of compositional data and contextual data may be performed via a processing pipeline that includes two steps. In a first step of the processing pipeline, a list of events that include attributes such as (x,y,z, Energy) obtained from interactions occurring at the detector 106 may be geometrically transformed to the world coordinate frame. A position of the data collection and fusing assembly 101 relative to the world coordinate frame may be identified by processing the contextual data from 108. Then synchronization is performed with the data collected by the detector 106 and the contextual sensor 108 and processed by the computing unit 102 to correlate the measured data with the position of the assembly in a second step of the processing pipeline.

In the second step of the processing pipeline, a list of events, such as probing or sampling events, with correlated global positions determined with respect to the world coordinate frame may be input to an image reconstruction algorithm. The image reconstruction algorithm may convert data regarding measured particles (e.g., as measured by the detector 106) into a 3D volumetric intensity representation of the environment. The 3D volumetric intensity representation (e.g., volumetric data) may include a grid or may be unstructured and corresponding to different subdivisions in 3D space. Alternatively, the volumetric data may include decompositions of the 3D space such that the volumetric data may be used to generate a contextual representation of the environment. The volumetric data may be constrained by the contextual sensor 108 to, for example, known locations within or on objects as determined by processing the contextual information from the contextual sensor 108 into occupancy grids.

The volumetric data may be converted to colorized heatmap data that indicates intensities of various parameters of interest (e.g., type of composition) using color and the heatmap data may be fused with the contextual data. In at least one embodiment, fusing the heatmap data with the contextual data may generate data that is visually fused for an end user and, optionally, displayed to the user at, for example, a display 110 of the visualization device 103. In addition, the fusing of the data may convert measurements obtained at the detector 106 to estimates of parameters away (e.g., at a distance) from the data collection and fusing assembly 101 within the environment. The processing pipeline may therefore, as an example, be applied to combine data from more than one component of the data collection and fusing assembly 101 to generate a merged representation of the data. In at least one embodiment, the merged representation may be a digital representation of the data.

In at least one embodiment, the second step of the processing pipeline, as described above, may be performed using image reconstructions techniques, such as those using in medical imaging, that employ statistical or iterative methods to estimate physical parameters from measured data. In at least one embodiment, as described herein, image reconstruction refers to conversion of raw data measured by the detector 106 and the contextual sensor 108 into an estimated parameter of interest in the world coordinate frame, or world space, which may also be referred to as inverse algorithms.

In another embodiment, the second step of the processing pipeline may be performed using histogram techniques that convert list mode count data with (x,y,z) coordinates into a volume of interest that is a volumetric representation of the list mode count data. The volumetric representation may have attributes of x, y, and z for a 3D case and may include additional attributes computed according to distribution estimation algorithms. As an example, a pre-processing step may optionally be included in the processing pipeline that precedes application of the image reconstruction algorithm. The pre-processing step may include extracting specific spectral features from the data collected by the detector 106, such as counts in a specific spectral peak to create volumetric maps that may be specific to a spectral line of interest. This may further include estimating background counts and then subtracting the estimated background counts from the signal counts of the data.

For example, the pre-processing step may be implemented for a specific isotope of interest when D-T API is used, which may allow bulk features to be extracted from the spectral data which may then be input to the image reconstruction algorithms. Multiple channels of data may be fed into the image reconstruction algorithms, which may produce multiple channels of output data. The channels may correspond to raw values of interest, such as energy as measured by the detector 106, for example. As another example, the multiple channels may correspond to specific chemical compositions of interest, such as compositions computed by the spectral decomposition algorithms configured to extract features from the spectral data. The spectral decomposition algorithms may also be applied to combine data from multiple types of detectors, such as combining data from gamma-ray and neutron detectors.

The spectral decomposition algorithms may further ingest data from the contextual sensor 108 as an additional input to refine and inform the volumetric parameter estimation of the volumetric data. In at least one embodiment, when multiple channels of data are processed, the volumetric data may be displayed to the end user as a set of different colors where each color represents a different channel resulting from data fusion. The colors may represent different energy values, for example, or different compositional elements of interest.

Furthermore, the second step of the processing pipeline may optionally include another pre-processing step that converts the list mode interaction data to bin mode data prior to ingestion by the image reconstruction algorithms. This pre-processing step may increase an efficiency of the image reconstruction algorithms depending on an amount and type of data. For example, certain types of the detector 106 may output data in a bin mode format, such as an entire spectrum. As a result, the operations included in the processing pipeline may be combined into simpler algorithms, or machine learning algorithms may instead be used that automatically combine at least some of the operations.

In at least one embodiment, a result of data fusion, e.g., fused data, may be output from the computing unit 102 to be visualized at the display 110 of the visualization device 103 as a fused or merged representation. In some examples, the merged representation may not be displayed but may instead be used by, for example, an autonomous robotic system or vehicle to steer and guide re-positioning of the autonomous system to collect data from object or regions of interest. The visualization device 103 may be an optional component of the compositional visualization system 100. For example, in at least some instances, the data collection and fusing assembly 101 may operate independent of visualization device 103.

The display 110 may be, for example, a screen at an interface of the visualization device 103, which may be a tablet, a mobile phone, a personal computing device, a computer, etc. In yet another embodiment, the visualization device 103 may include augmented reality (AR) devices and the display 110 may be viewed through AR goggles or glasses. As an example, visualization devices 103 having cameras, such as tablets or phones, may be used in combination with the AR device which may allow a user to observe objects of interest in the user’s direct line of view according to a field of view of the cameras. For example, the cameras of the tablets or phones may be aimed at an area that the data collection and fusing assembly 101 has scanned to view detected attributes associated with the objects. Furthermore, in at least one embodiment, the fused data may include a depiction of the environment, e.g., a map, indicating a presence of objects and regions of interest overlaid with measurements of one or more attributes. For example, the attribute measurements may be displayed as color indicators, as markers, via gradients of color, or some other visual representation of the respective attribute and measurement of the attribute.

At the visualization device 103, a user may select one or more attributes to be displayed. For example, the user may select concentrations of one or more specific elements or chemicals to be visualized at the display 110, which may be displayed as concentration heatmaps, as an example. In at least another embodiment, one or more automated detection algorithms may be run to search for a library of different chemical compositions, including different elements, chemicals, or isotopes. The chemical compositions may be displayed as a respective composition is detected and an alert or notification may be provided to the user at the display 110. Further, in at least one embodiment, when a concentration of a chemical is detected to rise above a threshold, the computing unit 102 may cause one or more of an alert to be presented at the display 110 or an associated heat map to be generated and displayed. Furthermore, a geometry of an object detected by data obtained via interrogation of the object by the particle generator 104 may be used to identify the object and label the object at the display 110.

In at least one embodiment, the data collection and fusing assembly 101 may be coupled to a mobile structure, such as a vehicle, a land-based autonomous robot, or an unmanned aerial vehicle (UAV). In some instances, the mobile structure may be guided or controlled (e.g., steered) using the contextual information obtained by the contextual sensor 108 and the attribute measurements obtained via interrogation of the environment by the particle generator 104. As one example, such as when the mobile structure is an autonomous robot or a UAV, the mobile structure may be guided using the merged digital representation without relying on generation of a visualization of the merged digital representation. For example, the merged digital representation may or may not be visualized at the visualization device 103 and in either situation, steering of the mobile structure may not depend on any visualization of the merged digital representation. Instead, generation of steering directions for the mobile structure may be computed and applied autonomously by the mobile structure.

Different embodiments of an apparatus for a data collection and fusing assembly of a compositional visualization system are illustrated in FIGS. 2 and 3. For example, FIG. 2 depicts a first arrangement of a data collection and fusing assembly 200, which may be an exemplary configuration of the data collection and fusing assembly 101 of FIG. 1. A set of Cartesian coordinate axes 299 is shown in FIG. 2 for contextualizing positions of the data collection and fusing assembly 200. Specifically, x-, y-, and z-axes are provided which are mutually perpendicular to one another. In some embodiments, a direction of gravity may be parallel to and coincident with the y-axis. In at least one embodiment, as shown in FIG. 2, the data collection and fusing assembly 200 includes a computing unit 202, a neutron generator 204, a detector 206, and a contextual sensor 208. In at least one embodiment, the computing unit 202, the neutron generator 204, the detector 206, and the contextual sensor 208 may operate as described above with reference to the computing unit 102, the particle generator 104, the detector 106, and the contextual sensor 108 of FIG. 1.

In at least one embodiment, the computing unit 202, the neutron generator 204, the detector 206, and the contextual sensor 208 may be included in a single unit forming the data collection and fusing assembly 200 such that re-positioning the unit causes the computing unit 202, the neutron generator 204, the detector 206, and the contextual sensor 208 to be re-positioning in unison. Re-positioning, herein, may refer to moving an object from one location to another. For example, computing unit 202, the neutron generator 204, the detector 206, and the contextual sensor 208 may all be mounted on a mobile vehicle and when the mobile vehicle is commanded to move, the computing unit 202, the neutron generator 204, the detector 206, and the contextual sensor 208 may be moved together, as compelled by the mobile vehicle.

Components of the data collection and fusing assembly 200 may be positioned such that neither an interrogation path 210 of the neutron generator 204, a reception path 212 of the detector 206, is obscured by any component (e.g., the neutron generator 204, the detector 206 and the contextual sensor 208). In at least one embodiment, this may be achieved by aligning the components along one side of the computing unit 202 to which each component may be physically connected via, for example, hardwired connections. This may circumvent interference of any one of the component with performance of the other components resulting from positioning of the components. Furthermore, the components may be positioned relative to one another such that interaction of a stream of particles generated by the neutron generator 204, which travel along the interrogation path, occurs at a location in the environment that is within the field of view 214 of the contextual sensor 208.

In at least one embodiment, the detector 206 may be positioned adjacent to the neutron generator 204 at a location relative to the neutron generator 204 that allows the detector 206 to receive detectable products (e.g., gamma-rays, neutrons, and alpha particles) produced at least in part by interaction of neutrons with materials in an environment surrounding the data collection and fusing assembly 200. For example, the neutron generator 204 may be selectively positioned in the data collection and fusing assembly 200 to emit particles (e.g., neutrons and alpha particles) along the interrogation path 210 with a known (e.g., predetermined) range, angle, rate of neutron generation, frequency of oscillation, neutron energy and acceleration, etc. The predetermined parameters of the interrogation path 210 may allow selection of a target for interrogation to be controlled accurately and may further allow the reception path 212 of the detector 206 to be accurately predicted. A positioning of the detector 206 relative to the neutron generator 204 may therefore be selected to accommodate the predicted reception path 212 to ensure that the detector 206 is placed at an optimal location to receive the detectable products. In at least one embodiment, such as when the neutron generator is a D-T API system, one detector 206 may be integrated with the neutron generator 204 rather than positioned adjacent to the neutron generator 204.

The contextual sensor 208 may have a field of view 214 that is indicated as an area between two dashed lines in FIG. 2 but is depicted as such as a representative and non-limiting example of the field of view 214. For example, a configuration (e.g., geometry, range, volume, etc.) of a region captured within the field of view 214 of the contextual sensor 208 may vary depending on the type of sensor used. As an example, when the contextual sensor employs a LiDAR system, the LiDAR system probe the environment in horizontal (e.g., relative to the x-axis) configuration along a 360 degree field of view. As shown in FIG. 2, the field of view of the contextual sensor 208 in such a configuration may not detect a region directly below ( e.g., with respect to the y-axis) the particle generator 204 along a surface 216 below the data collection and fusing assembly 200. Instead, the LiDAR system may collect data from a region at a distance away from the data collection and fusing assembly 200. However, as the data collection and fusing assembly 200 moves and is repositioned by performing SLAM, complete mapping of the surface 216 may be acquired.

While the contextual sensor 208 is positioned adjacent to the detector 206 in FIG. 2, in other embodiments, the contextual sensor 208 may be located in various alternate positions (e.g., as shown in FIG. 3) given that the contextual sensor 208 does not interfere with the interrogation path 210 or the reception path 212. For example, the contextual sensor 208 may be positioned vertically above the computing unit 202, horizontally adjacent to the computing unit, adjacent to the particle generator 204, or at various other locations. Moreover, the contextual sensor 208 may be located such that the field of view 214 of the contextual sensor 208 is not obstructed or obscured by the neutron generator 204 or the detector 206. Furthermore, the contextual sensor 208 may be located such that the contextual information obtained therefrom is relevant and readily aligned with a target of the neutron generator 204. In at least one embodiment a positioning, such as distance, orientation, offset along y, x, and x directions, of the contextual sensor 208 relative to one or more of the neutron generator 204 and the detector 206 may be predetermined and used to overlay the contextual information with measurements of environmental attributes, as described above.

In at least one embodiment, the data collection and fusing assembly 200 may be positioned to target a specific object or region of the environment according to a range of the interrogation path 210. As an example, when the neutron generator 204 is a D-T API neutron generator, the neutron generator 204 may have an effective range of 1 meter based on sensitivity. However, by combining the contextual information obtained by the contextual sensor 208 with the data collected by the detector 106 may effectively extend the range of the neutron generator 204. For example, the contextual information may be used to reposition the data collection and fusing assembly 200 relative to an object or a region identified to be of interest using fused data to increase an amount of data collected for the identified object or region. In at least one embodiment, increasing the amount of collected data may include increasing an area over the identified object or region for which data is obtained. In yet another embodiment, increasing the amount of collected data may include probing additional layers, e.g., layers internal to an outermost surface, of an identified object.

As an example, the data collection and fusing assembly 200 may first be positioned such that the neutrons from the neutron generator 204 interact with the surface 216. In at least one embodiment, the surface 216 may be a ground surface. In another embodiment, the surface 216 may be a wall of a building. In yet another embodiment, the surface 216 may be a wall of a subterranean structure, such as a cave. Upon probing the wall and subsurface interface of the wall (e.g., a region within and/or behind the wall) with the neutrons, the data collection and fusing assembly 200 may indicate, e.g., to an operator via a remote device with a display, that elevated concentrations of a chemical of interest is detected at the wall. The operator may further perform actions to cause the data collection and fusing assembly 200 to be adjusted to a different position that allows the neutron generator to probe deeper past the surface 216 and into an object 218 detected behind the surface 216. In at least one embodiment, when the surface 216 is a ground surface, the object 218 may be buried in the ground. In at least another embodiment, when the surface 216 is a wall of a structure, the object 218 may be buried or hidden in the wall. In at least one embodiment, the object 218 may be hidden from view but its presence may be revealed upon interrogation by the neutron generator 204. As an example, the object 218 may be a pipe, and the data collection and fusing assembly 200 may be used to both identify the object 218 as a pipe and to obtain compositional information of the pipe and any materials enclosed by the pipe. Moreover, outer and inner surfaces, boundaries and contours of the object 218 may be visualized using the data collection and fusing assembly 200.

In at least one embodiment, the use of fused data may leverage information corresponding to visible aspects of an environment (e.g., exterior surfaces and structures) collected from the contextual sensor 208 to obtain information corresponding to hidden or invisible aspects of the environment using data obtained via interrogation with the neutron generator 204. For example, the contextual information may be used to identify a region of the environment, e.g., automatically via a generated alert and/or by visual observation of a user, having attribute measurements that may be notably different from attribute measurements elsewhere in the environment and the neutron generator 204 may be further applied to the region from different positions relative to the region to provide higher resolution and/or more complete data regarding the region. In at least one embodiment, the neutron generator 204 may be used to detect and analyze internal structures, boundaries and/or contours of an object that may be either visible or hidden from view.

In at least one embodiment, the data collection and fusing assembly 200 may be mounted on a vehicle or movable structure that may be autonomous or manually controlled. For example, the data collection and fusing assembly 200 may be coupled to a robotic arm or a gantry that may allow a position of the data collection and fusing assembly 200 relative to a target object or region to be adjusted. In at least one embodiment, the robotic arm or the gantry may be mounted on a vehicle or other moveable or re-positionable structure. In at least another embodiment, the data collection and fusing assembly 200 may be sufficiently compact and lightweight to be re-positioned by an operator that may manually move the data collection and fusing assembly 200 to another position. As such, an operating mode of the data collection and fusing assembly 200 may depend at least in part on a mechanism by which the data collection and fusing assembly 200 may be re-positioned.

For example, if mounted on an autonomous vehicle, e.g., a land-based robot or a UAV, the data collection and fusing assembly 200 may operate in a continuous mode where each of the neutron generator 204, the detector 206, and the contextual sensor 208 may operate continuously. In other embodiments, the data collection and fusing assembly 200 may operate in a pulsed mode where the contextual sensor 208 may remain active continuously but the neutron generator 204 and the detector 206 may operate according to predetermined cycles and/or may be activated/deactivated according to detection of regions or objects of interest. As an example, the data collection and fusing assembly 200 may operate in a pulsed mode until an object is detected with elevated concentration of a specific chemical. The data collection and fusing assembly 200 may then be adjusted to operate in the continuous mode until the analysis of all areas of the object is complete after which the data collection and fusing assembly 200 may return to operation in the pulsed mode. In yet another example, the contextual information may be used to guide activation/deactivation of the neutron generator 204 and the detector 206.

In at least one embodiment, the data collection and fusing assembly 200 may operate in a targeted mode. For example, the contextual sensor 208 may be maintained continuously active but the neutron generator 204 and the detector 206 may be deactivated until an indication is received or obtained that an object or region of interest is detected. In one example, the region or object of interest may be indicated based on detection of a change in an environmental parameter from one or more additional sensors of the data collection and fusing assembly 200. For example, the data collection and fusing assembly 200 may include one or more temperature sensors, sensors for measuring particulate matter in air, and may perform detection algorithms to process data collected by the contextual sensor 208, such as an object detection algorithm, and a region or object of interest may be detected according to a change in a respective parameters, such as temperature, particulate concentration, and an output of the detection algorithms. Upon detecting the region of object of interest, the neutron generator 204 and the detector 206 may be activated and then deactivated once data collection is complete.

In another embodiment, the data collection and fusing assembly 200 may operate in the targeted mode, with the contextual sensor 208 maintained continuously active and the neutron generator 204 and the detector 206 deactivated until a tagged region or object is detected by the contextual sensor 208. As an example, the various items (e.g., regions and/or objects) may be tagged at external data sources and devices and sent to the computing unit 202 to be stored at the computing unit 202. The computing unit 202 may refer to the stored tagged items and used as references for identifying targets from the contextual information collected by the contextual sensor 208. Additionally or alternatively, the items may be tagged by the computing unit 202 using onboard algorithms and similarly stored thereat to be used as references. In yet another embodiment, the computing unit 202 may implement a machine learning model trained to identify regions and objects of interest from contextual information and/or information from additional sensors onboard the data collection and fusing assembly 200. The machine learning model may be used to infer targets from the contextual information.

A second arrangement of a data collection and fusing assembly 300 is shown in FIG. 3, which may be an exemplary configuration of the data collection and fusing assembly 101 of FIG. 1. A set of Cartesian coordinate axes 399 is shown in FIG. 3 for contextualizing positions of the data collection and fusing assembly 300. Specifically, x-, y-, and z-axes are provided which are mutually perpendicular to one another. In some embodiments, a direction of gravity may be parallel to and coincident with the y-axis. In at least one embodiment, the data collection and fusing assembly 300 includes a computing unit 302, a neutron generator 304, a detector 306, and a contextual sensor 308. In at least one embodiment, the computing unit 302, the neutron generator 304, the detector 306, and the contextual sensor 308 may operate as described above with reference to the corresponding components of the data collection and fusing assembly 101 FIG. 1 and the data collection and fusing assembly 200 of FIG. 2.

The data collection and fusing assembly 300 of FIG. 3 differs from the data collection and fusing assembly 200 of FIG. 2 in that the contextual sensor 308 is positioned away from the computing unit 302, the neutron generator 304, and the detector 306. In at least one embodiment, the data collection and fusing assembly 300 may include a first unit 301 that includes the computing unit 302, the neutron generator 304, and the detector 306, and a second unit 303 that includes the contextual sensor 308. In at least one embodiment, the first unit 301 may be mounted on a vehicle, such as an autonomous robot, a UAV, etc., and the second unit 303 may remain stationary. In at least another embodiment, both the first and second units 301, 303 may be mounted on a vehicle. In yet another embodiment, the first and second units 301, 303 may both be stationary and may be re-positioned manually, e.g., by an operator. In at least one embodiment, the first and second units 301, 303 may be re-positioned independent of one another.

In at least one embodiment, the contextual sensor 308 may be communicatively coupled to the computing unit 302 via a wireless communication link. A positioning of the contextual sensor 308 relative to the neutron generator 304 and the detector 306 may be selected such that the contextual sensor 308 does not interfere with an interrogation path 310 of the neutron generator 304 or a reception path 312 of the detector 306. Furthermore, the contextual sensor 308 may be located and re-positioned so that the neutron generator 304 and the detector 306 remain within a field of view 314 of the contextual sensor during operation of the data collection and fusing assembly 300. Moreover, the contextual sensor 308 may be positioned such that a location (e.g., a target) at which a stream of neutrons emitted along the interrogation path 310 interacts with the environment is captured within the field of view 314 of the contextual sensor 308.

In at least one embodiment, the contextual sensor 308 may be used, in addition to obtaining contextual information of the environment within its field of view 314, to track a position of the neutron generator 304 and the detector 306 in the environment. For example, the computing unit 302 may utilize information collected from the field of view 314 of the contextual sensor 308 to maintain the neutron generator 304 and the detector 306 within the field of view 314 of the contextual sensor 308. This may be achieved by commanding re-positioning of one or more of the first unit 301 of the data collection and fusing assembly 300 or of the second unit 303 of the data collection and fusing assembly 300.

The data collection and fusing assembly 300 may be used to extend a range of the neutron generator 304, as described above with respect to the data collection and fusing assembly 200 of FIG. 2. For example, the data collection and fusing assembly 300 may be used to identify and probe a surface 316 and, upon detection of attribute measurements that are of interest (e.g., indicating elevated or unusual measurements) the data collection and fusing assembly 300 may be re-positioned to allow the interrogation of an object 318 located inside beyond or behind the surface 316 and therefore otherwise hidden from view. In addition, the data collection and fusing assembly 300 may operate according to modes described above with respect to the data collection and fusing assembly 200 of FIG. 2.

In at least one embodiment, for either the data collection and fusing assembly 200 of FIG. 2 or the data collection and fusing assembly 300 of FIG, contextual information regarding the environment may be obtained from a pre-existing map or model of the environment that was previously generated, e.g., not generated in real-time during operation of the respective data collection and fusing assembly. For example, the pre-existing map or model may be stored at a memory of the computing units 202 and 302 and loaded upon request by an operator. In yet another embodiment, the pre-existing map or model may be used in addition to and/or in combination with the contextual information obtained from the contextual sensors 208 and 308.

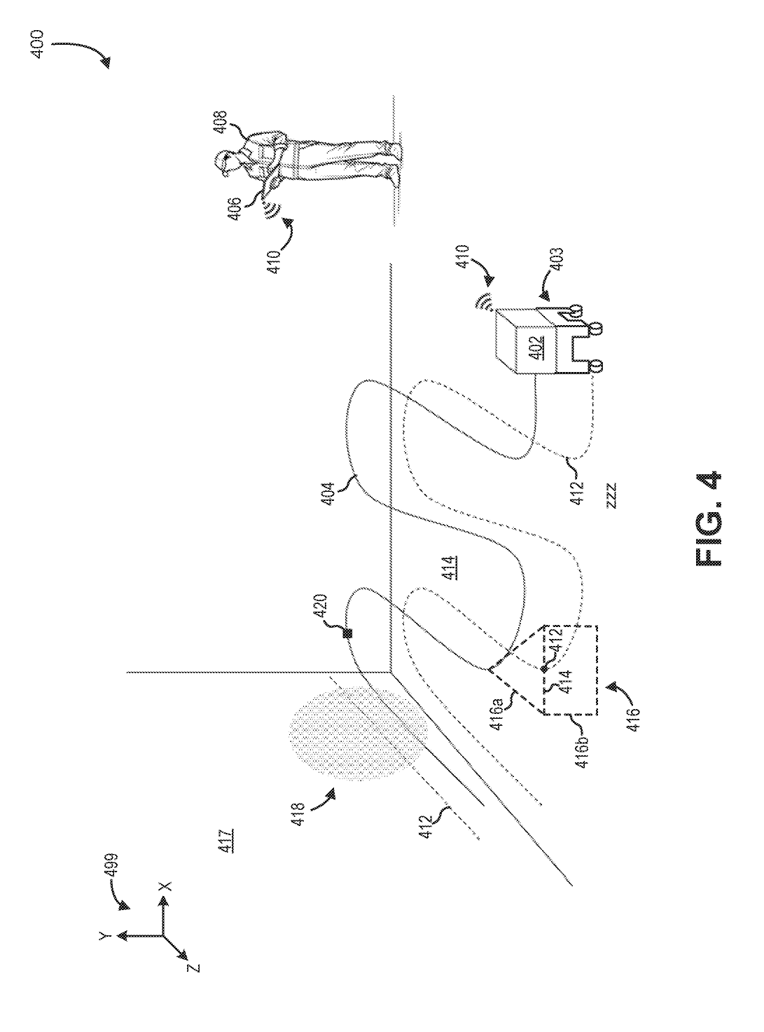

In at least one embodiment, as described above, the data collection and fusing assembly 200 may be coupled to a mobile apparatus or vehicle that may be moved in an autonomous or manual manner. For example, movement of at least a portion of a compositional visualization system 400 is illustrated in FIG. 4. A set of Cartesian coordinate axes 499 is shown in FIG. 4 for contextualizing positions of the data collection and fusing assembly 402. Specifically, x-, y-, and z-axes are provided which are mutually perpendicular to one another. In some embodiments, a direction of gravity may be parallel to and coincident with the y-axis. In at least one embodiment, the compositional visualization system 400 may include a data collection and fusing assembly 402, which may be configured as any of the data collection and fusing assemblies of FIGS. 1-3 (e.g., the data collection and fusing assemblies 101, 200, and 300). As illustrated in FIG. 4, the data collection and fusing assembly 402 may be located in a room having walls 417. In other examples, however, the data collection and fusing assembly 402 may be deployed in a variety environments, including environments without physical barrier such as the walls 417.

The data collection and fusing assembly 402 may follow a path of movement 404 to interrogate and model the environment, as indicated by a solid line in FIG. 4. In at least one embodiment, the data collection and fusing assembly 402 may travel horizontally (e.g., along the x-z plane) along the path of movement 404 as navigated by a vehicle 403 upon which the data collection and fusing assembly 402 may be mounted. In at least one embodiment, the vehicle 403 may be a motorized cart. For example, the vehicle 403 may be autonomous and guided by a machine learning model implemented at a computing unit of the data collection and fusing assembly 402, or may be manually guided by a remote device, which may be a visualization device 406 that is similar to the visualization device 103 of FIG. 1. In at least one embodiment, as depicted in FIG. 4, the visualization device 406 may be operated by an operator 408. In at least one embodiment, steering instructions to guide re-positioning of the data collection and fusing assembly 402 via movement of the vehicle 403 according to the path of movement 404 may be provided using contextual information obtained from a contextual sensor of the data collection and fusing assembly 402.

For example, when the vehicle 403 is autonomous, software or a machine learning model implemented at the computing unit may receive the contextual information and use the contextual information to plan the path of movement 404 and cause the vehicle 403 to follow the planned path. In at least one embodiment the planned path may be a path that maximizes an area probed by the data collection and fusing assembly 402. Alternatively, the planned path may be selected to provide a maximum resolution of data points obtained from a given area. In another embodiment, the path of movement 404 may be a predetermined path stored in a memory of the computing unit and retrieved therefrom to guide movement of the autonomous vehicle 403.

In yet another embodiment, when the vehicle 403 is manually steered, the path of movement 404 may be one of a variety of predetermined paths that may be selected by the operator and displayed as a visual aid for the operator along which the operator may maneuver the vehicle 403 using the visualization device 406. In a further embodiment, the path of movement 404 may not be predetermined and may, instead, be guided in real-time by the operator via the visualization device 406. In at least one embodiment, a machine learning model may predict the path of movement 404 in real-time using the contextual information and present the predicted path at the visualization device 406 as a recommended path to the operator 408, which the operator 408 may choose to use to guide steering of the vehicle 403.

In at least one embodiment, the visualization device 406 may be used to both receive requests from the operator 408, transmit the requests to the computing unit of the data collection and fusing assembly 402, and display a visualization of fused data obtained from the contextual sensor, a particle generator, and a detector of the data collection and fusing assembly 402. In at least one embodiment, the visualization device 406 may be communicatively coupled to the computing unit of the data collection and fusing assembly 402 by a wireless connection 410. For example, the wireless connection 410 may be Bluetooth, WiFi, WiMAX, a cellular network, mesh radios, among others. The wireless connection 410 may transmit wireless signals between one or more visualization devices 406 and the data collection and fusing assembly 402. At least one of the visualization devices 406 may be authorized to control re-positioning and operation of the data collection and fusing assembly 402.

In at least one embodiment, the compositional visualization system 400 may include one or more of the data collection and fusing assembly 402. For example, multiple units of the data collection and fusing assembly 402 may be deployed concomitantly to probe an environment in parallel, which may expedite analysis of the environment. Additionally or alternatively, the multiple units may include different particles generators, different contextual sensors, and/or different additional sensors to obtain a wide range of data collected for the environment. In at least one embodiment, the units may be communicatively linked to one another to allow information to be shared between the units to allow the data to be compiled and fused into a single visualization.

In at least one embodiment, as shown in FIG. 4, the data collection and fusing assembly 402 may collect data, such as measurements of attributes of the environment, from a measurement path 412, as indicated by a dashed line, along a surface 414 detected in the environment. For example, the surface 414 may be a floor 414 of a room and the data collection and fusing assembly 402 may be mounted on the vehicle 403 such that the data collection and fusing assembly 402 is elevated above, e.g., with respect to the y-axis, the floor 414. As the vehicle 403 is navigated along the path of movement 404, the data collection and fusing assembly 402 may collect data (e.g., via the particle generator and detector) from a field of view aimed downwards, e.g., along the y-axis, along the measurement path 412. Although the measurement path 412 is depicted as a dashed line, the data collection and fusing assembly 402 may collect data from a 3D volume rather than a 2D line, as illustrated by a cross-section 416 of a measurement volume from the data collection and fusing assembly 402. For example, in one exemplary operating mode of the data collection and fusing assembly 402, the measurement path 412 may represent a central focal point of an interrogation window of a particle generator of the data collection and fusing assembly 402 and may represent an alignment of the data collection and fusing assembly 402. As an example, as shown in FIG. 4, the data collection and fusing assembly 402 may aligned to interrogate the floor 414 of the room directly below the data collection and fusing assembly 402.

In at least one embodiment, the cross-section 416 of the measurement volume may represent a 2D area of a 3D volume defined by an operating window of the particle generator and the detector. The cross-section 416 may include a proximate portion 416a (e.g., proximate to the particle generator and detector) that is on a same side of the floor 414 as the data collection and fusing assembly 402. An area of the floor 414 that is probed by the particle generator may be similar to a field of a contextual sensor of the data collection and fusing assembly 402. For example, the proximate portion 416a may be above the floor 414. The cross-section 416 may also include a distal portion 416b (e.g., further away from the particle generator and detector than the proximate portion 416a) that extends into and below the floor 414.

As the vehicle 403 travels along the path of movement 404, the data collection and fusing assembly 402 may approach another surface of the room that is arranged perpendicular to the floor 414, e.g., the wall 417, which may be or include an object of interest 418, as indicated by a shaded area along the wall 417. For example, the object of interest 418 may be a region of the wall 417, some other type of object, or an object embedded in the wall. In at least one embodiment, upon detection of a surface corresponding to the object of interest 418 in the field of view of the contextual sensor, the alignment of the data collection and fusing assembly 402 may be adjusted to focus the interrogation window of the particle generator onto the object of interest 418. In at least one embodiment, this may be achieved by pivoting or rotating the data collection and fusing assembly 402 relative to the vehicle 403 such that the interrogation window of the particle generator, and the field of view of the contextual sensor, is focused on the object of interest 418 instead of the floor 414. The adjustment of the data collection and fusing assembly 402 may be performed automatically, based on detection of the data collection and fusing assembly 402 coming within a threshold proximity to the object of interest 418, or actuated manually by an operator.

In another exemplary operating mode of the data collection and fusing assembly 402, the data collection and fusing assembly 402 may instead collect data (e.g., both compositional data and contextual data) from all directions (e.g., 360 degrees) simultaneously. In such embodiments, as the data collection and fusing assembly 402 approaches the object of interest 418, such as when the data collection and fusing assembly 402 is at point 420 along the path of movement 404, data may be collected from both along the object of interest 418 and along the floor 414 concurrently. As such, the particle generator and the detector of the data collection and fusing assembly 402 may operate with a localized, fixed field of view, may have a localized field of view that can be adjusted (e.g., pivoted and/or rotated), or may interrogate collect data from the environment in all directions around the data collection and fusing assembly 402.

In at least one embodiment, the data collection and fusing assembly 402 may detect an attribute measurement of interest, such as a change in density, a change in concentration of an element, or a change in chemical composition, chemical ratios, isotopic composition, etc., and indicate that a region or object of interest may be present. For example, the alarming software described above may be used to generate an alert which may be displayed at the visualization device 406. In response to the alert, one or more of the particle generator, detector, or contextual sensor of the data collection and fusing assembly 402 may be automatically or manually adjusted to target the object of interest 418 instead of, or in addition to, the floor 414, as illustrated at FIG. 4. As a result, the measurement path 412 may be shifted to the object of interest 418 to allow the particle generator to interrogate an area behind the object of interest 418.

While the data collection and fusing assembly 402 is described and depicted as re-positionable by coupling the data collection and fusing assembly 402 to the vehicle 403, in at least some embodiments, the data collection and fusing assembly 402 may collect data without being re-positioned. For example, the data collection and fusing assembly 402 may be positioned with one or more objects moving through a field of view of the contextual sensor, which may overlap with a particle emission window of the particle generator and a detection window of the detector. As an example, the objects may be arranged on a conveyor belt in motion and the data collection and fusing assembly 402 may collect data for an object as the object passes through the field of view of the data collection and fusing assembly 402.

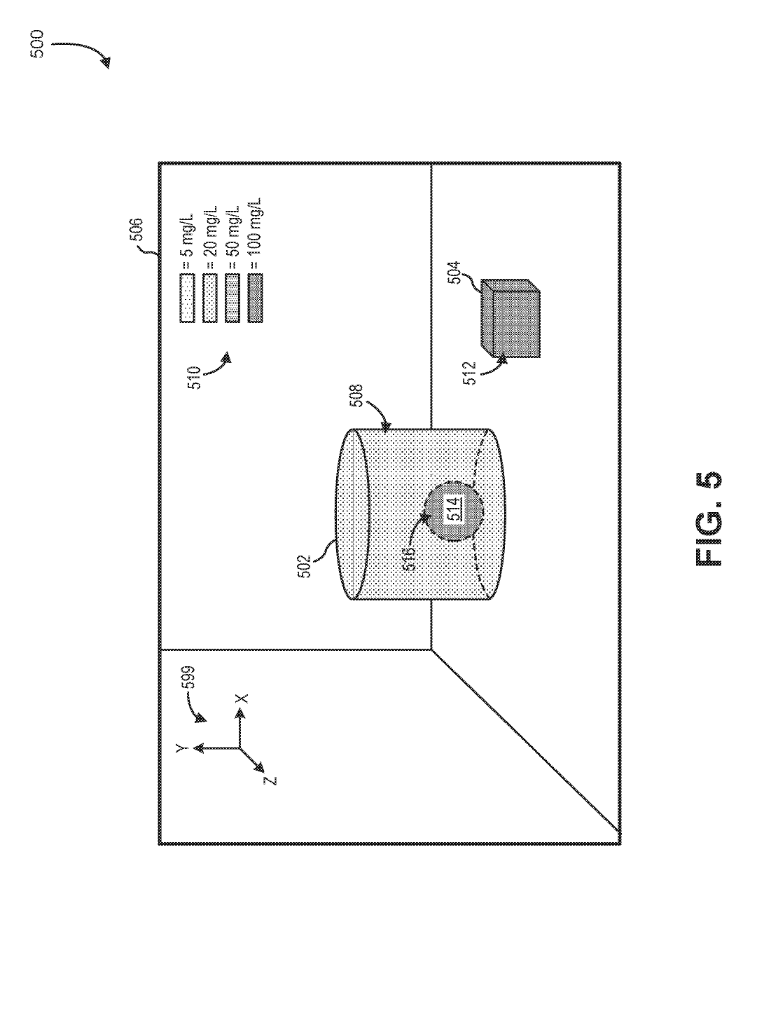

In at least one embodiment, fused data generated at a compositional visualization system may be displayed to a user or operator at a user display, as described above. For example, the fused data may be visually presented at display screen located at one or more of a hand-held remote device, such as the visualization device 406 of FIG. 4, at a data collection and fusing assembly portion of the compositional visualization system, or at a user terminal located at a base station that is communicatively linked to the compositional visualization system. An example of a visual display 500 of the fused data is illustrated in FIG. 5.

The visual display 500 may include Cartesian coordinate axes 599 to contextualize positions of objects and an environment depicted at the visual display 500, relative to a data collection and fusing assembly that is collecting and fusing data shown at the visual display 500. A first object 502 and a second object 504 may be captured in a field of view 506 of the visual display 500. Depiction of the first object 502 and the second object 504 may be displayed according to a 3D model of the environment generated based on contextual information obtained by a contextual sensor.

A visualization of the first object 502 at the visual display 500 may be overlaid with a first compositional representation 508. The first compositional representation 508 may be a visual indicator of, for example, a concentration of a chemical detected and quantified by the data collection and fusing assembly within an inner volume of the first object 502, and may correspond to a concentration included in an index 510 also displayed at the visual display 500. In at least one embodiment, as shown in FIG. 5, the concentration of the chemical may be indicated as shading, or a color, at locations in the visual display 500 where the concentration meets or exceeds a threshold. For example, at the first object 502, the concentration of the chemical may be at least 5 mg/L, according to the index 510. Corresponding shading (or color) may be overlaid with the first object 502 at the visual display 500.

A higher concentration of the chemical may be detected at the second object 504, which is depicted in FIG. 5 as a second compositional representation 512 that is shown as darker shading (or a different or more intense color) relative to the first compositional representation 508. For example, the concentration of the chemical may be measured to be at least 100 mg/L at the second object 504, according to the index 510. In at least one embodiment, the first compositional representation 508 and the second compositional representation 512 may be displayed as real-time visualizations of compositional data, as collected from a detector, merged with a 3D model of the environment. The first compositional representation 508 and the second compositional representation 512 may further indicate both an external (e.g., outer) and an internal (e.g., inner) geometry of the first object 502 and the second object 504, respectively.

The data collection and fusing assembly may further capture compositional information for a third object 514 that is enclosed within the first object 502 (as indicated by a dashed outline). The third object 514 may be detected to have a higher concentration of the chemical than the inner volume of the first object 514. A third compositional representation 516 may thus be generated and overlaid with the third object 514 in the visual display 500, where the third compositional representation 516 may be displayed as a real-time visualization of compositional data collected from within the first object 502. For example, as shown in FIG. 5, the third compositional representation 516 may be indicated as a higher concentration of the chemical by depicting the third compositional representation with darker shading than the inner volume of the first compositional representation 508. The third compositional representation may also indicate an outer and inner geometry of the third object 514.

It will be appreciated that the visual display 500 shown in FIG. 5 is a non-limiting example of how fused or merged data may be presented to a viewer. For example, other embodiments may include variations in how an environment is depicted, how compositional representations are displayed, what type of information is presented at a visual display, as well as how many different types of compositional data is shown overlaid with a model of the environment. Moreover, display of the fused or merged data may be optional and operation of the compositional visualization system may be independent of whether or not the data is displayed. For example, the data may be collected and used in an autonomous implementation of a compositional visualization system to guide operation of the system without displaying the collected and processed data.

Data collected by a data collection and fusing assembly of a compositional visualization system may be collected, analyzed, and fused according to more than one sequence of steps. Different embodiments of a workflow of a data collection and fusing assembly are illustrated in FIGS. 6-8. As shown in FIG. 6, in a first embodiment of a workflow 600 implemented at a data collection and fusing assembly (e.g., at computing unit thereof), data fusion may occur before data obtained via interrogation of an environment by a particle generator is analyzed to generate measurements of attributes of the environment. In at least one embodiment, the data collection and fusing assembly may be any one of the data collection and fusing assembly 101 of FIG. 1, 200 of FIG. 2, 300 of FIG. 3 or 402 of FIG. 4, the computing unit may be any one of the computing unit 102 of FIG. 1, 202 of FIG. 2, or 302 of FIG. 3, and the particle generator may be any one of the particle generator 104 of FIG. 1, 204 of FIG. 2 or 304 of FIG. 3,

In at least one embodiment, the workflow 600 may include emitting neutrons from the particle generator into the environment at a first step 602. In at least one embodiment, emitting the neutrons from the particle generator may include receiving, at the particle generator, a command from a computing unit, such as the computing unit 102 of FIG. 1, 202 of FIG. 2, or 302 of FIG. 3, of the data collection and fusing assembly which may cause activation of the particle generator to generate one or more of neutrons and alpha particles. The command from the computing unit may be generated based on an indication that data collection is to be initiated, such as through input from an operator at a remote visualization device, such as any of the visualization device 103 of FIG. 1 or 406 of FIG. 4. For example, the operator may input a request to activate the particle generator and/or a contextual sensor of the data collection and fusing assembly, such as any one of the contextual sensor 108 of FIG. 1, 208 of FIG. 2, or 308 of FIG. 3, which may be received by at the computing unit. In response to the request, the computing may command activation of the particle generator and/or the contextual sensor.

Upon interaction of the neutrons with materials in the environment, detectable products, such as gamma-rays, and neutrons, may be received, at a second step 604, at the computing unit from a detector, such as any one of the detector 106 of FIG. 1, 206 of FIG. 2, or 306 of FIG. 3, of the data collection and fusing assembly. In at least one embodiment, the detectable products may be detected by the detector as measurement data such as a gamma ray, neutron, and/or alpha particle count. The measurement data may be transmitted to the computing unit where algorithms for transforming the measurement data into another format, such as concentration, mass percent, a ratio of one element or chemical to another, density values, etc., may be applied. Concurrently, e.g., concurrent with one or more of the first and second steps 602 and 604, the computing unit may receive contextual information at a third step 606 from the contextual sensor, which may be used, e.g., algorithms applied to the contextual information at the computing unit, to generate a model of the environment in real-time (e.g., within seconds of receiving the contextual information). Alternatively, the model of the environment may be an externally generated model, such as from devices separate from the data collection and fusing assembly.

At a fourth step 608 of the workflow 600, the data received from the detector at the computing unit may be fused with the model of the environment by the computing unit to generate characteristic gamma-ray histograms corresponding to regions of the environment. The computing unit may apply further algorithms to analyze the gamma-ray characteristics at a fifth step 610 to obtain measurements of attributes of the environments, including physical and/or chemical compositions, and further instruct the attribute measurements to be displayed at the visualization device as a fused or merged representation of the contextual information and the attribute measurements.

A second embodiment of a workflow 700 is shown at FIG. 7, which may be implemented at a data collection and fusing assembly (e.g., at computing unit thereof), such as, for example, any one of the data collection and fusing assembly 101 of FIG. 1, 200 of FIG. 2, 300 of FIG. 3 or 402 of FIG. 4. In at least one embodiment, the computing system may be any one of the computing unit 102 of FIG. 1, 202 of FIG. 2, or 302 of FIG. 3. The workflow 700, in contrast to the workflow 600 of FIG. 6, data fusion may instead occur after data obtained via interrogation of an environment by a particle generator is analyzed to generate measurements of attributes of the environment. The particle generator may be, for example, any one of the particle generator 104 of FIG. 1, 204 of FIG. 2 or 304 of FIG. 3.

In least one embodiment, the workflow 700 includes emitting neutrons from the particle generator into the environment in a first step 702. Upon interaction of the neutrons with materials in the environment, detectable products, such as gamma-rays, alpha particles, and neutrons, may be received, at a second step 704, at the computing unit from a detector of the data collection and fusing assembly. In at least one embodiment, emitting the neutrons from the particle generator may include receiving, at the particle generator, a command from the computing unit which may cause activation of the particle generator to generate one or more of neutrons and alpha particles. The command from the computing unit may be generated based on an indication that data collection is to be initiated, such as through input from an operator at a remote visualization device, such as any of the visualization device 103 of FIG. 1 or 406 of FIG. 4. For example, the operator may input a request to activate the particle generator and/or a contextual sensor of the data collection and fusing assembly, such as any one of the contextual sensor 108 of FIG. 1, 208 of FIG. 2, or 308 of FIG. 3, which may be received by at the computing unit. In response to the request, the computing may command activation of the particle generator and/or the contextual sensor.

Upon interaction of the neutrons with materials in the environment, detectable products, such as gamma-rays, alpha particles, and neutrons, may be received, at a second step 704, at the computing unit from a detector, such as any one of the detector 106 of FIG. 1, 206 of FIG. 2, or 306 of FIG. 3, of the data collection and fusing assembly. In at least one embodiment, the detectable products may be detected by the detector as measurement data such as a gramma ray, neutron, and/or alpha particle count.

At a third step 706 of the workflow 700, data received from the detector at the computing unit may be analyzed for characteristic gamma-ray histograms. In at least one embodiment, analyzing the data may include applying algorithms to the data, at the computing unit, to perform one or more computations on the data to convert the data into another format, such as the histograms. However, in other examples, the measurement data may instead be converted to other formats, such as concentration, mass percent, a ratio of one element or chemical to another, density values, etc., using suitable algorithms. Concurrently with one or more of the first, second, and third steps 702, 704, and 706, the computing unit may receive contextual information, at a fourth step 708. The contextual information may be received from a contextual sensor of the data collection and fusing assembly and may be used, e.g., algorithms applied to the contextual information at the computing unit, to generate a model of the environment in real-time (e.g., within seconds of receiving the contextual information). Alternatively, the model of the environment may be an externally generated model, such as from devices separate from the data collection and fusing assembly.

At a fifth step 710 of the workflow 700, the attribute measurements from the detector may be fused with the model of the environment to generate a compositional model of the environment. In at least one embodiment, the computing unit may apply algorithms to the attribute measurements and the model of the environment to merge, fuse, or otherwise combine the data to produce the compositional model. The compositional model may include physical compositions and/or chemical compositions and the computing unit may further instruct the compositional model to displayed at the visualization device as a fused visualization.

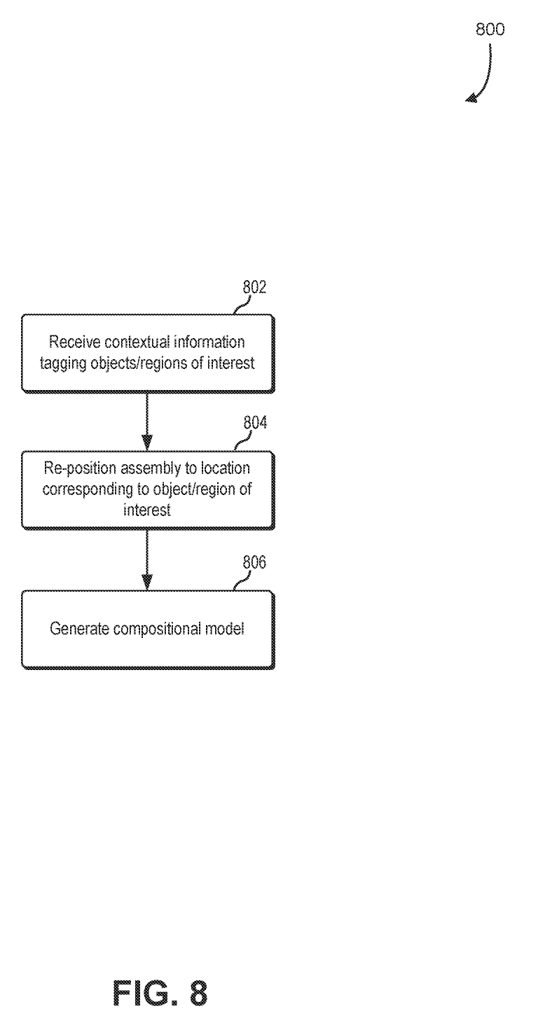

A third embodiment of a workflow 800 implemented at a data collection and fusing assembly (e.g., at computing unit thereof), is depicted in FIG. 8. In at least one embodiment, the data collection and fusing assembly may be any one of the data collection and fusing assembly 101 of FIG. 1, 200 of FIG. 2, 300 of FIG. 3 or 402 of FIG. 4, and the computing unit may be any one of the computing unit 102 of FIG. 1, 202 of FIG. 2, or 302 of FIG. 3. In at least one embodiment, the workflow 800 may include utilizing tagged data to guide interrogation of an environment. For example, at a first step 802 of the workflow 800, contextual information with tags indicating objects and/or regions of the environment of interest may be received at the computing unit of the data collection and fusing assembly.

In at least one embodiment, the contextual information may be received from a contextual sensor of the data collection and fusing assembly, such as any one of the contextual sensor 108 of FIG. 1, 208 of FIG. 2, or 308 of FIG. 3. In at least another embodiment, the contextual information may have been obtained previously and may be stored at a memory of the computing unit to be retrieved from the memory by one or more processors of the computing unit. In yet another embodiment, the contextual information may be transmitted, upon request from the computing unit, to the computing unit from a remote storage location, such as a remote database, a cloud platform, another computing device, etc. The tags may include, for example, metadata providing information regarding the tagged object or region. In at least one embodiment, the tagged contextual information may be generated at an external device separate from the data collection and fusing assembly and delivered to the computing unit of the data collection and fusing assembly via a wireless or hardwired communication link. In another embodiment, a machine learning model may be implemented at the computing unit to infer and tag the objects or regions of interest as contextual information is obtained from a contextual sensor of the data collection and fusing assembly or from another storage location or another computing device.

At a second step 804, the workflow 800 may include re-positioning the data collection and fusing assembly according to the tagged contextual information. In at least one embodiment, re-positioning the data collection and fusing assembly may include using, at the computing unit, the tagged objects and/or regions as targets for interrogation and applying navigation software (e.g., algorithms for navigation implemented at the computing unit) to generate steering directions to command movement of a vehicle supporting the data collection and fusing assembly. In at least one embodiment, the vehicle may be the vehicle 403 of FIG. 4. For example, an operator may input a request at a visualization device (e.g., the visualization device 103 of FIG. 1 or 406 of FIG. 4) to reposition the data collection and fusing assembly to target interrogation one or more of the tagged objects and/or regions with the particle generator. The computing unit may receive the request, perform computations to identify how the data collection and fusing assembly is located relative to the targeted tagged objects and/or regions based on the contextual information from the contextual sensor, and generate directions for guiding repositioning of the data collection and fusing assembly. The computing unit may command movement of the vehicle supporting the data collection and fusing assembly according or transmit the directions to a computing device controlling movement of the vehicle.

In at least one embodiment, the navigation software may include one or more machine learning models trained to generate steering directions using the contextual information. For example, a machine learning model may identify objects and/or regions of interest based on the contextual information and tag the objects and/or regions of interest. In some instances the machine learning model may additionally use data collected from a detector of the data collection and fusing assembly, such as any one of the detector 106 of FIG. 1, 206 of FIG. 2, or 306 of FIG. 3, to identify and tag objects and/or regions of interest. A machine learning model may further infer steering directions based on the contextual information and/or the data collected at the detector. For example, the machine learning model may utilize the contextual information to identify a location of the data collection and fusing assembly relative to the tagged objects and/or regions and generate steering directions based on the identified location. The steering directions output by the machine learning model may be used by the computing unit to command movement of the vehicle or may be sent to a computing device controlling movement of the vehicle.

At a third step 806, the workflow 800 may include generating a compositional model of the environment according to either of the workflows 600 or 700 of FIGS. 6 or 7. The compositional model generated at the computing unit may be displayed at a visualization device as a fused visualization.

In at least some embodiments, with respect to any of the workflows 600, 700, or 800 of FIGS. 6-8, raw measurement data collected by the detector may fused with the contextual data instead of measurement data that has been processed and converted into a different format. A resulting visualization may thereby depict the raw data imposed on a 3D model of the environment, e.g., using color or other visual indicators.

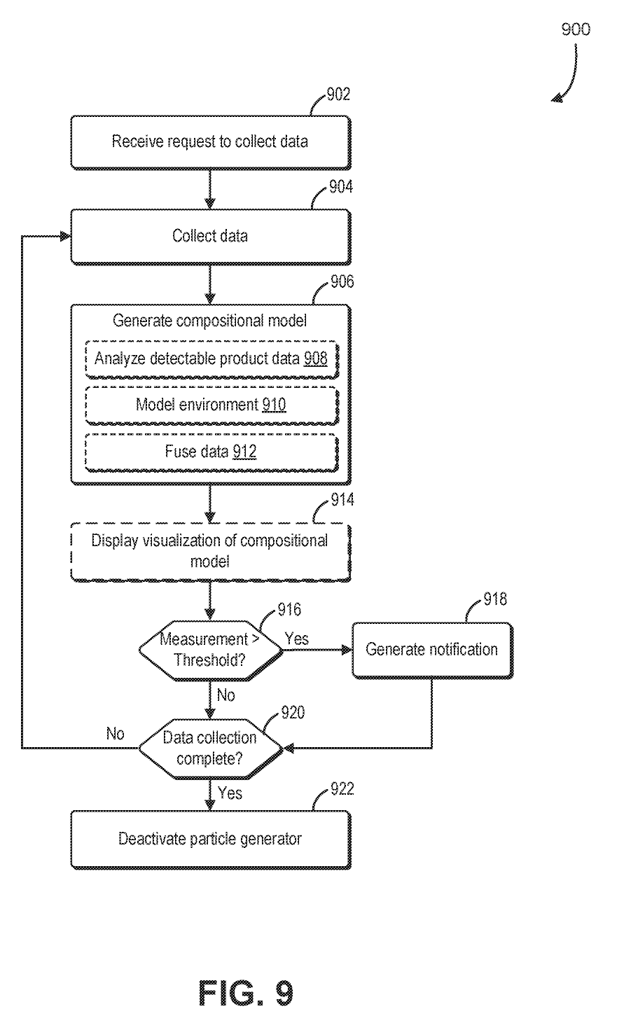

An example of a method 900 for operating a compositional visualization system is depicted in FIG. 9. In at least one embodiment, the compositional visualization system may be any one of the compositional visualization systems 100 or 400 of FIGS. 1 and 4, and may include any of the visualization devices and data collection and fusing assemblies illustrated in FIGS. 1-4. Furthermore, the compositional visualization system may include a computing unit with computer-executable instructions to perform any of the workflows 600, 700, and 800 of FIGS. 6-8, respectively.

Some or all of the method 900 may be performed by one or more computer systems configured with executable instructions and/or other data and may be implemented as executable instructions executing collectively on one or more processors. The executable instructions and/or other data may be stored on a non-transitory computer-readable storage medium (e.g., a computer program persistently stored on magnetic, optical, or flash media). For example, some or all of the method 900 may be performed by any suitable system, such as the computing unit 102 of FIG. 1, 202 of FIG. 2, or 302 of FIG. 3, any of which may be an embodiment of the computing device 1100 of FIG. 11. The method 900 includes a series of operations where data from different devices is compiled and merged to generate a single representation of the compiled and merged data.

At block 902, the method 900 may include receiving a request, at the computing unit of the data collection and fusing assembly, to collect data. In at least one embodiment, the request may be received from the visualization device. In response to the request, at block 904, the method may include collecting data from one or more of a contextual sensor and a detector by activating one or more of the contextual sensor, a particle generator, and the detector. In at least one embodiment, collecting the data may further include using the contextual sensor to guide positioning of the data collection and fusing assembly (e.g., by providing steering directions to a vehicle to which the data collection and fusing assembly is coupled) to probe an environment surrounding the data collection and fusing assembly using the particle generator.

At block 906, the method 900 may include generating a compositional model of the environment, where the compositional model may be produced from fused data to provide information regarding attributes (e.g., physical composition, such as density, and chemical composition such as concentration of chemicals, elemental content, elemental ratios, chemical ratios, isotopic composition, etc.) of the environment. In at least one embodiment, generating the compositional model may include analyzing data collected for detectable products at block 908, modeling the environment at block 910, and fusing data at block 912. It will be noted that blocks 908, 910, and 912 are shown with dashed outlines to indicate that these operations may be performed in different orders, according to different workflows, as described above with reference to FIGS. 6 and 7. Furthermore, a workflow that incorporates and utilizes tagging of objects of regions in the environment, such as the workflow 800 of FIG. 8, may also be performed to generate the compositional model.

In at least one embodiment, analyzing the detectable products at block 908 may include performing computations on data obtained from the detector which receives secondary particles and radiation produced during interaction of primary particles (e.g., neutrons) emitted from the particle generator with materials in the environment. The computations performed on the data may convert the data to measurements of attributes detected in the environment, as described above with respect to FIG. 1. In at least one embodiment, modeling the environment at block 910 may include using contextual information from the contextual sensor to create a N-dimensional model of the environment, where N may be equal to two or greater. In at least one embodiment, fusing the data at block 912 may include aligning the data from the detector with the data from the contextual sensor and combining the aligned data to generate the compositional model.

At block 914, the method 900 may include optionally (as indicated by a dashed box) displaying the compositional model. In at least one embodiment, the compositional model may be displayed at a display screen of the visualization device as a component of a merged or fused representation. In a further embodiment, the representation may include a model or map of the environment overlaid with attribute measurements. For example, the attribute measurements may be depicted using color, point clouds, markers, etc., and may be presented at a corresponding location in the model or map of the environment. In at least one embodiment, the attribute measurements displayed at the visualization device may be selected by an operator using the visualization device, which may allow one or more attribute measurement to be displayed for viewing. Furthermore, in at least one embodiment the visualization displayed at the visualization device may reflect a current field of view of the contextual sensor, although, in some instances an option to retrieve previous views may be requested and retrieved from the memory of the computing unit.

At block 916, the method 900 may include confirming if at least one measured attribute is greater than a threshold. For example, the threshold may be a predetermined level above which contamination by a chemical is indicated, presence of a specific type of object is confirmed, concentration of a chemical or material is detected, or an attribute or combination of attributes is unusual relative to the surroundings or compared to a baseline. The threshold may be incorporated and utilized by alarming software algorithms, as described previously, to detect when one or more attribute measurements are a level of interest.

If the measured attribute is greater than the threshold, the method 900 may include proceeding to block 918 to generate a notification. In at least some embodiments, the notification may be an audio or visual signal activated at the display device or at a vehicle or autonomous robotic system that the compositional visualization system is coupled to. Upon generating the notification, the method 900 may include continuing to block 920. If the measured attribute does not exceed the threshold, the method 900 may include continuing to block 920.

At block 920, the method 900 may include confirming if data collection is complete. In at least one embodiment data collection may be deemed complete when the operator indicates completion via the visualization device. In another embodiment, data collection may be deemed complete when the vehicle supporting the data collection and fusing assembly reaches an end point of a predetermined path of movement or measurement path used to guide movement of the vehicle. In a further embodiment, data collection may be deemed complete when interrogation of a target object or region is complete and attribute measurements return to baseline levels. Moreover, in some instances, data collection may be deemed complete when a person is detected (e.g., via one or more motion sensors) to approach the data collection and fusing assembly, which may automatically trigger a shutdown process of at least a portion of the compositional visualization system.

If data collection is not complete, the method 900 may include returning to block 904 to continue collecting data. Newly collected data may be used to update the merged representation, as well as display of the merged representation. For example, the merged representation may be updated at a target refresh rate that may depend on a frequency of data collection and/or capabilities of a computing unit used to process the collected data. If data collection is indicated to be complete, the method 900 may include proceeding to block 922 to deactivate at least the particle generator. In some embodiments, one or more of the detector or the contextual sensor may additionally be deactivated.

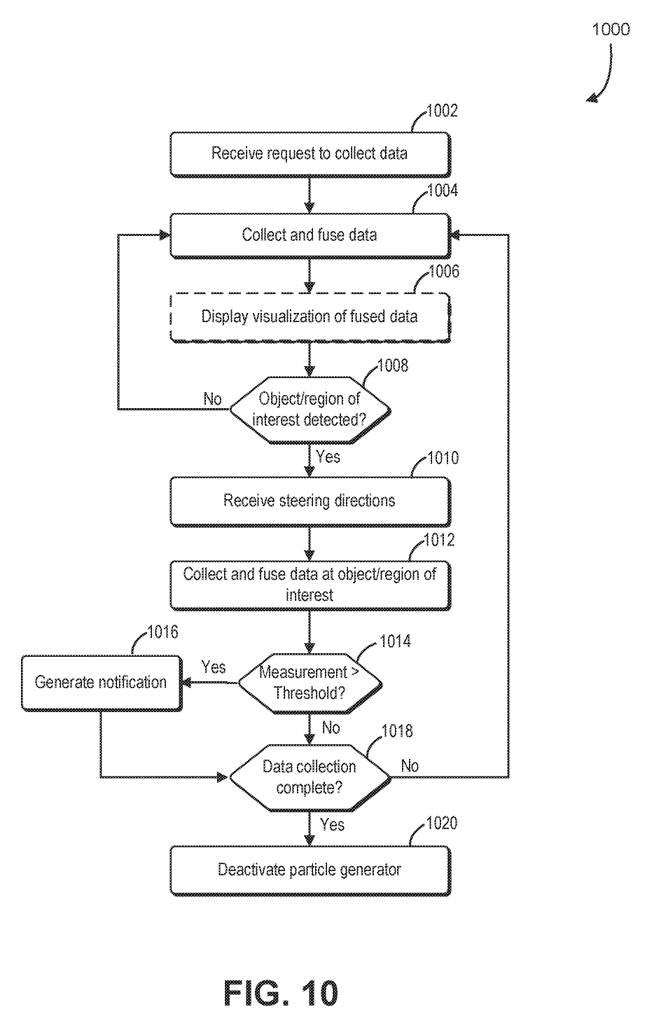

An example of a method 1000 for operating a compositional visualization system that utilizes information from a contextual sensor to guide re-positioning of a data collection and fusing assembly of the compositional visualization system is shown in FIG. 10. In at least one embodiment, the compositional visualization system may be any one of the compositional visualization systems 100 or 400 of FIGS. 1 and 4, and may include any of the visualization devices and data collection and fusing assemblies illustrated in FIGS. 1-4. Furthermore, the compositional visualization system may include a computing unit with computer-executable instructions to perform any of the workflows 600, 700, and 800 of FIGS. 6-8, respectively.

Some or all of the method 1000 may be performed by one or more computer systems configured with executable instructions and/or other data and may be implemented as executable instructions executing collectively on one or more processors. The executable instructions and/or other data may be stored on a non-transitory computer-readable storage medium (e.g., a computer program persistently stored on magnetic, optical, or flash media). For example, some or all of the method 1000 may be performed by any suitable system, such as the computing unit 102 of FIG. 1, 202 of FIG. 2, or 302 of FIG. 3, any of which may be an embodiment of the computing device 1100 of FIG. 11. The method 1000 includes a series of operations where data from a contextual sensor of the data collection and fusing assembly is used to guide re-positioning of a particle generator used to probe an environment surrounding the data collection and fusing assembly.

At block 1002, the method 1000 may include receiving a request, at the computing unit of the data collection and fusing assembly, to collect data. In at least one embodiment, the request may be received from the visualization device. In response to the request, at block 1004, the method may include collecting data from one or more of a contextual sensor and a detector by activating one or more of the contextual sensor, a particle generator, and the detector. In at least one embodiment, collecting the data may further include using the contextual sensor to guide positioning of the data collection and fusing assembly (e.g., by providing steering directions to a vehicle to which the data collection and fusing assembly is coupled) to probe an environment surrounding the data collection and fusing assembly using the particle generator.

At block 1004, the method 1000 may further include fusing the collected data. In at least one embodiment collecting and fusing the data may be performed as described at block 906 of the method 900 depicted in FIG. 9 and in conjunction with the above description of FIG. 1. Alternatively, in other embodiments, the fused data may include raw data collected by the detector of the data collection and fusing assembly and contextual data. The fused data may be optionally displayed as a visualization at block 1006 of the method 1000 (as indicated by a dashed block). In at least one embodiment, displaying the visualization may be performed as described at block 914 of the method 900 of FIG. 9. In other embodiments, the fused data may not be displayed but instead used directly by the computing unit to identify objects or regions of interest and/or to generate steering directions.

At block 1008, the method 1000 may include confirming if an object or region of interest is detected based on the fused data. In at least one embodiment, the data collection and fusing assembly may be continuously re-positioned while collecting data to follow a path of movement or a measurement path that may be pre-determined. An object or region of interest may be identified when one or more attribute measurements are detected to change beyond a threshold amount. By re-positioning the data collection and fusing assembly, a target location corresponding to the detected object or region of interest may be mapped and identified relative to a positioning of the data collection and fusing assembly in the environment.

At block 1010, the method 1000 may include receiving steering instructions to cause a vehicle to which the data collection and fusing assembly is coupled to navigate to the target location for higher resolution and/or more extensive probing of the target location. In at least one embodiment, the steering directions may be received from software implemented at the computing unit, which may include inferences generated by a machine learning model based on the contextual information from the contextual sensor. In another embodiment, the steering directions may be received from an operator transmitting instructions to the computing unit through the visualization device. In yet another embodiment, the steering directions may be generated based on tagging of objects or regions of the environment.

At block 1012, the method 1000 may include collecting and fusing data at the target location corresponding to the object or region of interest. The data may be collected and fused as described at block 906 of the method 900 of FIG. 9.

At block 1014, the method 1000 may include confirming if at least one measured attribute is greater than a threshold. For example, the threshold may be a predetermined level above which contamination by a chemical is indicated, presence of a specific type of object is confirmed, concentration of a chemical or material is detected, or an attribute or combination of attributes is unusual relative to the surroundings or compared to a baseline. The threshold may be incorporated and utilized by alarming software algorithms, as described previously, to detect when one or more attribute measurements are above a level of interest.

If the measured attribute is greater than the threshold, the method 1000 may include proceeding to block 1016 to generate a notification. In at least some embodiments, the notification may be an audio or visual signal activated at the display device or at a vehicle or autonomous robotic system that the compositional visualization system is coupled to. Upon generating the notification, the method 1000 may including continuing to block 1018. If the measured attribute does not exceed the threshold, the method 1000 may include continuing to block 1018.

At block 1018, the method 1000 may include confirming if data collection is complete. In at least one embodiment data collection may be deemed complete when the operator indicates completion via the visualization device. In another embodiment, data collection may be deemed complete when the vehicle supporting the data collection and fusing assembly reaches an end point of a predetermined path of movement or measurement path used to guide movement of the vehicle. In a further embodiment, data collection may be deemed complete when interrogation of the object or region of interest is complete and attribute measurements return to baseline levels. Moreover, in some instances, data collection may be deemed complete when a person is detected (e.g., via motion sensor) to approach the data collection and fusing assembly, which may automatically trigger a shutdown process of at least a portion of the compositional visualization system.

If data collection is not complete, the method 1000 may include returning to block 1004 to continue collecting and fusing data. Newly collected and fused data may be used to update the fused data, as well as a visualization of the fused data, if the fused data is to be displayed. If data collection is indicated to be complete, the method 1000 may include proceeding to block 1020 to deactivate at least the particle generator. In some embodiments, one or more of the detector or the contextual sensor may additionally be deactivated.

FIG. 11 is an illustrative, simplified block diagram of a computing device 1100 that can be used to practice at least one embodiment of the present disclosure. In at least one embodiment, the computing device 1100 may be used to implement and perform operations of a compositional visualization system, as described above with reference to FIGS. 1-10. For example, the computing device 1100 may be implemented at one or more of a visualization device or a data collection and fusing assembly of the compositional visualization system. In at least a further embodiment, the computing device may be an embodiment of the computing unit 102, 202, and 302 of FIGS. 1-3, respectively. In various embodiments, the computing device 1100 includes any appropriate device operable to send and/or receive requests, messages, or information over an appropriate network and convey information back to a user of the device. The computing device 1100 may be used to implement any of the systems illustrated and described above. For example, the computing device 1100 may be configured for use as a data server, a web server, a portable computing device, a personal computer, a cellular or other mobile phone, a handheld messaging device, a laptop computer, a tablet computer, a set-top box, a personal data assistant, an embedded computer system, an electronic book reader, or any electronic computing device. The computing device 1100 may be implemented as a hardware device, a virtual computer system, or one or more programming modules executed on a computer system, and/or as another device configured with hardware and/or software to receive and respond to communications (e.g., web service application programming interface (API) requests) over a network.

As shown in FIG. 11, the computing device 1100 may include one or more processors 1102 that, in embodiments, communicate with and are operatively coupled to a number of peripheral subsystems via a bus subsystem. In some embodiments, these peripheral subsystems include a storage subsystem 1106, comprising a memory subsystem 1108 and a file/disk storage subsystem 1110, one or more user interface input devices 1112, one or more user interface output devices 1114, and a network interface subsystem 1116. Such storage subsystem 1106 may be used for temporary or long-term storage of information.

In some embodiments, the bus subsystem 1104 may provide a mechanism for enabling the various components and subsystems of computing device 1100 to communicate with each other as intended. Although the bus subsystem 1104 is shown schematically as a single bus, alternative embodiments of the bus subsystem utilize multiple buses. The network interface subsystem 1116 may provide an interface to other computing devices and networks. The network interface subsystem 1116 may serve as an interface for receiving data from and transmitting data to other systems from the computing device 1100. In some embodiments, the bus subsystem 1104 is utilized for communicating data such as details, search terms, and so on. In an embodiment, the network interface subsystem 1116 may communicate via any appropriate network that would be familiar to those skilled in the art for supporting communications using any of a variety of commercially available protocols, such as Transmission Control Protocol/Internet Protocol (TCP/IP), User Datagram Protocol (UDP), protocols operating in various layers of the Open System Interconnection (OSI) model, File Transfer Protocol (FTP), Universal Plug and Play (UpnP), Network File System (NFS), Common Internet File System (CIFS), and other protocols.

The network, in an embodiment, is a local area network, a wide-area network, a virtual private network, the Internet, an intranet, an extranet, a public switched telephone network, a cellular network, an infrared network, a wireless network, a satellite network, or any other such network and/or combination thereof, and components used for such a system may depend at least in part upon the type of network and/or system selected. In an embodiment, a connection-oriented protocol is used to communicate between network endpoints such that the connection-oriented protocol (sometimes called a connection-based protocol) is capable of transmitting data in an ordered stream. In an embodiment, a connection-oriented protocol can be reliable or unreliable. For example, the TCP protocol is a reliable connection-oriented protocol. Asynchronous Transfer Mode (ATM) and Frame Relay are unreliable connection-oriented protocols. Connection-oriented protocols are in contrast to packet-oriented protocols such as UDP that transmit packets without a guaranteed ordering. Many protocols and components for communicating via such a network are well known and will not be discussed in detail. In an embodiment, communication via the network interface subsystem 1116 is enabled by wired and/or wireless connections and combinations thereof.

In some embodiments, the user interface input devices 1112 includes one or more user input devices such as a keyboard; pointing devices such as an integrated mouse, trackball, touchpad, or graphics tablet; a scanner; a barcode scanner; a touch screen incorporated into the display; audio input devices such as voice recognition systems, microphones; and other types of input devices. In general, use of the term “input device” is intended to include all possible types of devices and mechanisms for inputting information to the computing device 1100. In some embodiments, the one or more user interface output devices 1114 include a display subsystem, a printer, or non-visual displays such as audio output devices, etc. In some embodiments, the display subsystem includes a cathode ray tube (CRT), a flat-panel device such as a liquid crystal display (LCD), light emitting diode (LED) display, or a projection or other visualization device. In general, use of the term “output device” is intended to include all possible types of devices and mechanisms for outputting information from the computing device 1100. The one or more user interface output devices 1114 can be used, for example, to present user interfaces to facilitate user interaction with applications performing processes described and variations therein, when such interaction may be appropriate.

In some embodiments, the storage subsystem 1106 provides a computer-readable storage medium for storing the basic programming and data constructs that provide the functionality of at least one embodiment of the present disclosure. The applications (programs, code modules, instructions), when executed by one or more processors in some embodiments, provide the functionality of one or more embodiments of the present disclosure and, in embodiments, are stored in the storage subsystem 1106. These application modules or instructions can be executed by the one or more processors 1102. In various embodiments, the storage subsystem 1106 additionally provides a repository for storing data used in accordance with the present disclosure. In some embodiments, the storage subsystem 1106 comprises a memory subsystem 1108 and a file/disk storage subsystem 1110.

In embodiments, the memory subsystem 1108 includes a number of memories, such as a main random-access memory (RAM) 1118 for storage of instructions and data during program execution and/or a read only memory (ROM) 1120, in which fixed instructions can be stored. In some embodiments, the file/disk storage subsystem 1110 provides a non-transitory persistent (non-volatile) storage for program and data files and can include a hard disk drive, a floppy disk drive along with associated removable media, a Compact Disk Read Only Memory (CD-ROM) drive, an optical drive, removable media cartridges, or other like storage media.

In some embodiments, the computing device 1100 includes at least one local clock 1124. The at least one local clock 1124, in some embodiments, is a counter that represents the number of ticks that have transpired from a particular starting date and, in some embodiments, is located integrally within the computing device 1100. In various embodiments, the at least one local clock 1124 is used to synchronize data transfers in the processors for the computing device 1100 and the subsystems included therein at specific clock pulses and can be used to coordinate synchronous operations between the computing device 1100 and other systems in a data center. In another embodiment, the local clock is a programmable interval timer.

The computing device 1100 could be of any of a variety of types, including a portable computer device, tablet computer, a workstation, or any other device described below. Additionally, the computing device 1100 can include another device that, in some embodiments, can be connected to the computing device 1100 through one or more ports (e.g., USB, a headphone jack, Lightning connector, etc.). In embodiments, such a device includes a port that accepts a fiber-optic connector. Accordingly, in some embodiments, this device converts optical signals to electrical signals that are transmitted through the port connecting the device to the computing device 1100 for processing. Due to the ever-changing nature of computers and networks, the description of the computing device 1100 depicted in FIG. 11 is intended only as a specific example for purposes of illustrating the preferred embodiment of the device. Many other configurations having more or fewer components than the system depicted in FIG. 11 are possible.

In some embodiments, data may be stored in a data store (not depicted). In some examples, a “data store” refers to any device or combination of devices capable of storing, accessing, and retrieving data, which may include any combination and number of data servers, databases, data storage devices, and data storage media, in any standard, distributed, virtual, or clustered system. A data store, in an embodiment, communicates with block-level and/or object level interfaces. The computing device 1100 may include any appropriate hardware, software and firmware for integrating with a data store as needed to execute aspects of one or more applications for the computing device 1100 to handle some or all of the data access and business logic for the one or more applications. The data store, in an embodiment, includes several separate data tables, databases, data documents, dynamic data storage schemes, and/or other data storage mechanisms and media for storing data relating to a particular aspect of the present disclosure. In an embodiment, the computing device 1100 includes a variety of data stores and other memory and storage media as discussed above. These can reside in a variety of locations, such as on a storage medium local to (and/or resident in) one or more of the computers or remote from any or all of the computers across a network. In an embodiment, the information resides in a storage-area network (SAN) familiar to those skilled in the art, and, similarly, any necessary files for performing the functions attributed to the computers, servers or other network devices are stored locally and/or remotely, as appropriate.

In an embodiment, the computing device 1100 may provide access to content including, but not limited to, text, graphics, audio, video, and/or other content that is provided to a user in the form of HyperText Markup Language (HTML), Extensible Markup Language (XML), JavaScript, Cascading Style Sheets (CSS), JavaScript Object Notation (JSON), and/or another appropriate language. The computing device 1100 may provide the content in one or more forms including, but not limited to, forms that are perceptible to the user audibly, visually, and/or through other senses. The handling of requests and responses, as well as the delivery of content, in an embodiment, is handled by the computing device 1100 using PHP: Hypertext Preprocessor (PHP), Python, Ruby, Perl, Java, HTML, XML, JSON, and/or another appropriate language in this example. In an embodiment, operations described as being performed by a single device are performed collectively by multiple devices that form a distributed and/or virtual system.

In an embodiment, the computing device 1100 typically will include an operating system that provides executable program instructions for the general administration and operation of the computing device 1100 and includes a computer-readable storage medium (e.g., a hard disk, random access memory (RAM), read only memory (ROM), etc.) storing instructions that if executed (e.g., as a result of being executed) by a processor of the computing device 1100 cause or otherwise allow the computing device 1100 to perform its intended functions (e.g., the functions are performed as a result of one or more processors of the computing device 1100 executing instructions stored on a computer-readable storage medium).

In an embodiment, the computing device 1100 operates as a web server that runs one or more of a variety of server or mid-tier applications, including Hypertext Transfer Protocol (HTTP) servers, FTP servers, Common Gateway Interface (CGI) servers, data servers, Java servers, Apache servers, and business application servers. In an embodiment, computing device 1100 is also capable of executing programs or scripts in response to requests from user devices, such as by executing one or more web applications that are implemented as one or more scripts or programs written in any programming language, such as Java®, C, C# or C++, or any scripting language, such as Ruby, PHP, Perl, Python, or TCL, as well as combinations thereof. In an embodiment, the computing device 1100 is capable of storing, retrieving, and accessing structured or unstructured data. In an embodiment, computing device 1100 additionally or alternatively implements a database, such as one of those commercially available from Oracle®, Microsoft®, Sybase®, and IBM® as well as open-source servers such as MySQL, Postgres, SQLite, MongoDB. In an embodiment, the database includes table-based servers, document-based servers, unstructured servers, relational servers, non-relational servers, or combinations of these and/or other database servers.

Embodiments of the disclosure can be described in view of the following:

Systems and methods of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a compositional visualization system. The compositional visualization system may include a sensor to collect contextual information of an environment, a particle generator to generate, based, at least in part, on the contextual information, a first stream comprising one or more types of particles. The system may also include a detector to receive a second stream comprising one or more detectable products, where the second stream may be generated by interaction of the first stream with the environment. The system may also include one or more processors and memory including computer-executable instructions that, when executed by the one or more processors, cause the system to: transform the received second stream into compositional data, and merge the compositional data with the contextual information of the first sensor to generate a merged digital representation. Other embodiments of this aspect include corresponding computer systems, apparatus, and computer programs recorded on one or more computer storage devices, each configured to perform the actions of the methods.

Implementations may include one or more of the following features. The particle generator may be a neutron generator, and the one or more types of particles may include neutrons. The one or more detectable products may include one or more of gamma-rays and neutrons. The computer-executable instructions, when executed by the one or more processors, may further cause the system to use the contextual information to generate a model of the environment. The compositional data may include histograms of characteristic gamma-rays. The compositional data corresponds to one or more attributes of the environment, and the one or more attributes may include one or more of physical composition, chemical composition, or isotopic composition. The physical composition may include a density of a material. The chemical composition may include one or more of a concentration of chemicals, elemental ratios, chemical ratios, and elemental content. The merged digital representation may be displayed at one or more devices, and the one or more devices may include one or more of a mobile phone, a tablet, a personal computing device, a computer, an augmented reality device, or a portion of the compositional visualization system that may include one or more of the sensor, the particles generator, the detector, or the sensor to collect the contextual information. Implementations of the described techniques may include hardware, a method or process, or computer software on a computer-accessible medium.

One general aspect includes a method for compositional visualization. The method may include obtaining contextual information of an environment from a sensor, generating, at a particle generator, based, at least in part, on the contextual information, a first stream comprising one or more types of particles. The method may also include receiving a second stream comprising one or more detectable products at a detector, where the second stream is generated by interaction of the first stream with the environment. The method may further include transforming the received second stream into compositional data, and merging the compositional data with the contextual information of the sensor to generate a merged digital representation to guide re-positioning of the sensor, the particle generator, and the detector. Other embodiments of this aspect include corresponding computer systems, apparatus, and computer programs recorded on one or more computer storage devices, each configured to perform the actions of the methods.

Implementations may include one or more of the following features. Generating the first stream may include identifying an object or region of interest from the contextual information as a target for the particle generator. The second stream may be transformed into the compositional data before the compositional data is merged with the contextual information. The second stream may be transformed into the compositional data after the compositional data is merged with the contextual information. Merging the compositional data with the contextual information may include correlating the compositional data with the contextual information according to time to generate merged data, and converting the merged data based, at least in part, on a world coordinate frame. The method may further include displaying the merged digital representation as a model of the environment overlaid with a compositional model. Implementations of the described techniques may include hardware, a method or process, or computer software on a computer-accessible medium.

One general aspect includes a deployable apparatus for compositional visualization. The deployable apparatus may include one or more processors and memory including computer-executable instructions that, when executed by the one or more processors, cause the apparatus to: generate a model of an environment using contextual information collected by a sensor; generate measurements of one or more attributes of the environment using data obtained by a detector, where the detector is to detect a set of detectable products produced via interactions of a set of particles with the environment at a location identified based, at least in part, on the contextual information; combine the measurements of the one or more attributes with the model of the environment to generate a fused representation; and update the fused representation based, at least in part, on changes to the contextual information collected by the sensor. Other embodiments of this aspect include corresponding computer systems, apparatus, and computer programs recorded on one or more computer storage devices, each configured to perform the actions of the methods.

Implementations may include one or more of the following features. The sensor may be a light detection and ranging (lidar) system. The deployable apparatus may be a single unit that includes the sensor, the detector, a particle generator that generates the set of particles, where the sensor, the detector, and particle generator are re-positioned in the environment in unison. In another embodiment, a first unit of the deployable apparatus may include the detector and a particle generator that generates the set of particles, and a second unit of the deployable apparatus may include the sensor, where the first unit and the second unit are re-positionable independent of one another. A location of the interactions of the set of particles with the environment may correspond to a target identified based, at least in part, on an object or region that is tagged in the model of the environment. Implementations of the described techniques may include hardware, a method or process, or computer software on a computer-accessible medium.

The specification and drawings are, accordingly, to be regarded in an illustrative rather than a restrictive sense. However, it will be evident that various modifications and changes may be made thereunto without departing from the scope of the invention as set forth in the claims. Likewise, other variations are within the scope of the present disclosure. Thus, while the disclosed techniques are susceptible to various modifications and alternative constructions, certain illustrated embodiments thereof are shown in the drawings and have been described above in detail. It should be understood, however, that there is no intention to limit the invention to the specific form or forms disclosed but, on the contrary, the intention is to cover all modifications, alternative constructions and equivalents falling within the scope of the invention, as defined in the appended claims.

The use of the terms “a” and “an” and “the” and similar referents in the context of describing the disclosed embodiments (especially in the context of the following claims) is to be construed to cover both the singular and the plural, unless otherwise indicated or clearly contradicted by context. The terms “comprising,” “having,” “including” and “containing” are to be construed as open-ended terms (i.e., meaning “including, but not limited to,”) unless otherwise noted. The term “connected,” when unmodified and referring to physical connections, is to be construed as partly or wholly contained within, attached to or joined together, even if there is something intervening. Recitation of ranges of values in the present disclosure are merely intended to serve as a shorthand method of referring individually to each separate value falling within the range unless otherwise indicated and each separate value is incorporated into the specification as if it were individually recited. The use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and the corresponding set may be equal. The use of the phrase “based on,” unless otherwise explicitly stated or clear from context, means “based at least in part on” and is not limited to “based solely on.”

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., could be either A or B or C, or any nonempty subset of the set of A and B and C. For instance, in the illustrative example of a set having three members, the conjunctive phrases “at least one of A, B, and C” and “at least one of A, B, and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present.

Operations of processes described can be performed in any suitable order unless otherwise indicated or otherwise clearly contradicted by context. Processes described (or variations and/or combinations thereof) can be performed under the control of one or more computer systems configured with executable instructions and can be implemented as code (e.g., executable instructions, one or more computer programs or one or more applications) executing collectively on one or more processors, by hardware or combinations thereof. In some embodiments, the code can be stored on a computer-readable storage medium, for example, in the form of a computer program comprising a plurality of instructions executable by one or more processors. In some embodiments, the computer-readable storage medium is non-transitory.

The use of any and all examples, or exemplary language (e.g., “such as”) provided, is intended merely to better illuminate embodiments of the invention and does not pose a limitation on the scope of the invention unless otherwise claimed. No language in the specification should be construed as indicating any non-claimed element as essential to the practice of the invention.

Embodiments of this disclosure are described, including the best mode known to the inventors for carrying out the invention. Variations of those embodiments will become apparent to those of ordinary skill in the art upon reading the foregoing description. The inventors expect skilled artisans to employ such variations as appropriate and the inventors intend for embodiments of the present disclosure to be practiced otherwise than as specifically described. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated or otherwise clearly contradicted by context.

All references, including publications, patent applications, and patents, cited are hereby incorporated by reference to the same extent as if each reference were individually and specifically indicated to be incorporated by reference and were set forth in its entirety.

What is claimed is:

1. A compositional visualization system, comprising:
a sensor to collect contextual information of an environment;
a particle generator to generate, based, at least in part, on the contextual information, a first stream comprising one or more types of particles;
a detector to receive a second stream comprising one or more detectable products, wherein the second stream is generated by interaction of the first stream with the environment;
one or more processors; and
memory including computer-executable instructions that, when executed by the one or more processors, cause the system to:
transform the received second stream into compositional data; and
merge the compositional data with the contextual information of the first sensor to generate a merged digital representation.

2. The compositional visualization system of claim 1, wherein the particle generator is a neutron generator, and wherein the one or more types of particles comprises neutrons.

3. The compositional visualization system of claim 1, wherein the one or more detectable products comprises one or more of gamma-rays and neutrons.

4. The compositional visualization system of claim 1, wherein the computer-executable instructions, when executed by the one or more processors, further cause the system to use the contextual information to generate a model of the environment.

5. The compositional visualization system of claim 1, wherein the compositional data comprises histograms of characteristic gamma-rays.

6. The compositional visualization system of claim 1, wherein the compositional data corresponds to one or more attributes of the environment, and wherein the one or more attributes comprise one or more of physical composition, chemical composition, or isotopic composition.

7. The compositional visualization system of claim 6, wherein the physical composition comprises a density of a material.

8. The compositional visualization system of claim 6, wherein the chemical composition comprises one or more of concentration of chemicals, elemental ratios, chemical ratios, and elemental content.

9. The compositional visualization system of claim 1, wherein the merged digital representation is displayed at one or more devices, and wherein the one or more devices comprises one or more of a mobile phone, a tablet, a personal computing device, a computer, an augmented reality device, or a portion of the compositional visualization system that comprises one or more of the sensor, the particles generator, the detector, or the sensor to collect the contextual information.

10. A method for compositional visualization, comprising:
obtaining contextual information of an environment from a sensor;
generating, at a particle generator, based, at least in part, on the contextual information, a first stream comprising one or more types of particles;
receiving a second stream comprising one or more detectable products at a detector, wherein the second stream is generated by interaction of the first stream with the environment;
transforming the received second stream into compositional data; and
merging the compositional data with the contextual information of the sensor to generate a merged digital representation to guide re-positioning of the sensor, the particle generator, and the detector.

11. The method of claim 10, wherein generating the first stream comprises identifying an object or region of interest from the contextual information as a target for the particle generator.

12. The method of claim 10, wherein the second stream is transformed into the compositional data before the compositional data is merged with the contextual information.

13. The method of claim 10, wherein the second stream is transformed into the compositional data after the compositional data is merged with the contextual information.

14. The method of claim 10, wherein merging the compositional data with the contextual information comprises correlating the compositional data with the contextual information according to time to generate merged data, and converting the merged data based, at least in part, on a world coordinate frame.

15. The method of claim 10, further comprising displaying the merged digital representation as a model of the environment overlaid with a compositional model.

16. A deployable apparatus for compositional visualization, the deployable apparatus comprising:
one or more processors; and
memory including computer-executable instructions that, when executed by the one or more processors, cause the apparatus to:
generate a model of an environment using contextual information collected by a sensor;
generate measurements of one or more attributes of the environment using data obtained by a detector, wherein the detector is to detect a set of detectable products produced via interactions of a set of particles with the environment at a location identified based, at least in part, on the contextual information;
combine the measurements of the one or more attributes with the model of the environment to generate a fused representation; and
update the fused representation based, at least in part, on changes to the contextual information collected by the sensor.

17. The deployable apparatus of claim 16, wherein the sensor is a light detection and ranging (LiDAR) system.

18. The deployable apparatus of claim 16, wherein the deployable apparatus is a single unit comprising the sensor, the detector, a particle generator that generates the set of particles, and wherein the sensor, the detector, and particle generator are re-positioned in the environment in unison.

19. The deployable apparatus of claim 16, wherein a first unit of the deployable apparatus comprises the detector and a particle generator that generates the set of particles, and a second unit of the deployable apparatus comprises the sensor, and wherein the first unit and the second unit are re-positionable independent of one another.

20. The deployable apparatus of claim 16, wherein a location of the interactions of the set of particles with the environment corresponds to a target identified based, at least in part, on an object or region that is tagged in the model of the environment.
